(19) United States
(12) Patent Application Publication
(10) Pub. No.: US 2026/0235647 A1
(43) Pub. Date: Aug. 13, 2026

(54) SENSORED INSULATION PLUG

(71) Applicant: 3M INNOVATIVE PROPERTIES COMPANY, St. Paul, MN (US)

(72) Inventors: Douglas B. Gundel, Cedar Park, TX (US); Gunther A. J. Stollwerck, Krefeld (DE)

(21) Appl. No.: 19/469,617

(22) PCT Filed: Mar. 25, 2024
(86) PCT No.: PCT/IB2024/052850

§ 371 Date: Sep. 26, 2025

Related U.S. Application Data
(60) Provisional application No. 63/495,321, filed on Apr. 11, 2023.

(51) Int. Cl. G01R 15/16; G01R 31/12

(52) U.S. Cl. CPC G01R 15/16; G01R 31/1272

(57) ABSTRACT

Sensored insulation plug (1, 2) for a medium voltage or high-voltage separable connector (10), operable to sense an elevated voltage, and comprising a plug body (140), a contact piece (175), connectable with the connector on elevated voltage, an embedded discrete coupling capacitor (151), and an integrated sensing capacitor (150), operable as a high-voltage capacitor in a sensing voltage divider for sensing the elevated voltage and comprising a high-voltage electrode (162), a tubular sensing electrode (170), embedded in the insulating material (610) and arranged around an axial section of the high-voltage electrode; and a dielectric (180). The coupling capacitor (151) comprises a coupling electrode (160), connected to the contact piece, and an opposed counter electrode (171) and is operable to harvest energy, superimpose signals over the elevated voltage, extract signals from the elevated voltage, detect a partial discharge signal in the elevated voltage, detect the presence or absence of an elevated voltage, sense an elevated voltage at a low accuracy or detect a zero crossing of the elevated voltage.

### FIELD OF THE INVENTION

This disclosure relates to insulation plugs for separable connectors in medium-voltage and high-voltage power distribution networks. In particular, it relates to such plugs that have a voltage sensing feature. The disclosure also relates to power distribution networks with separable connectors having such sensored plugs installed therein and to processes of upgrading separable connectors with such sensored insulation plugs.

### BACKGROUND

Power distribution networks transmitting electrical power in large geographic areas, such as national grids, are becoming more complex to operate because nowadays consumers can generate energy on their premises and feed it into these networks in a decentralized manner, at unpredictable times and in unpredictable amounts. Network operators place voltage sensing devices in electrical installations at key locations of their network, such as in switchgears or transformers, to collect information about the current state of their power network.

In a medium-voltage or high-voltage power distribution network, a power cable is typically connected to network apparatus, such as switchgears or transformers, by a separable connector, also often referred to as a removable power connector or T-body connector, mounted at the end of the cable. Such separable connectors have a front cavity to receive a protruding portion of a bushing of the apparatus, and a connection element on high or medium voltage. The connection element is in electrical contact with the cable conductor and can be mechanically and electrically connected to the bushing, e.g. via a threaded stud accessible through an opposed rear cavity of the separable connector. After installation, the rear cavity is filled by inserting a so-called insulation plug, which insulates the connection element.

Elements of a voltage sensor for measuring the elevated voltage of the connection element of a separable connector—and thereby the elevated voltage of the power cable—can be integrated into the insulation plug, making it a “sensored insulation plug”. A voltage sensor of that type is described, for example, in the U.S. Pat. No. 6,031,368 and in the European patent application published as EP 3 070 481 A1. Often, such sensors use voltage dividers to sense the elevated voltage. For the elevated voltages involved capacitive voltage dividers are generally considered advantageous as they do not require a conductive connection with components on the elevated voltage and are thereby inherently safer.

As used herein, the high-voltage portion of a voltage divider is the portion that is electrically arranged between a signal contact, at which a divided voltage can be picked up, and a contact for connection to the elevated voltage which is to be sensed. The low-voltage portion of the voltage divider is the portion that is electrically arranged between that signal contact and a contact for connection of the voltage divider to electrical ground. The divided voltage varies proportionally with the elevated voltage, it is therefore also referred to herein as the “signal voltage”. The dividing ratio, i.e. the proportionality factor between the elevated voltage and the signal voltage, depends on the ratio of the total impedance of the high-voltage portion to the total impedance of the low-voltage portion of the voltage divider. By measuring the signal voltage of the signal contact and applying the proportionality factor, the elevated voltage of the connection element can be sensed. A signal wire may be connected to the signal contact to lead the signal voltage to some measurement circuitry outside the sensored insulation plug.

In order to sense the voltage of the connection element with high accuracy, a capacitive voltage divider (a “sensing voltage divider”) may be used, of which the dividing ratio is precisely known. The high-voltage portion of such a sensing voltage divider may comprise one capacitor or a plurality of capacitors. The high-voltage portion is often a single capacitor, the “sensing capacitor” or the “high-voltage capacitor” of the voltage divider. Advantageously the sensing capacitor, or the entire high-voltage portion, is accommodated in the sensored insulation plug, making use of the insulative properties of the body of the insulation plug.

Discrete capacitors that have both a high voltage rating and a larger capacity are generally rare and expensive. The term “discrete capacitor”, as used herein, refers to an individual capacitor having an individual nominal capacitance that exists independently from the structure of the insulation plug. A surface-mount capacitor is an example of a discrete capacitor. Where a voltage sensor for elevated voltages requires a capacitor having a high voltage rating and a comparatively small capacity, instead of a discrete capacitor, an integrated capacitor can be used, i.e. a capacitor that is formed by structural elements of the insulation plug rather than by a separate, discrete electrical device. For example, an integrated capacitor can be formed by two conductive patches on opposed sides of a circuit board, with the material of the circuit board forming the dielectric of the integrated capacitor. A further example of an integrated capacitor is a capacitor formed by a metal block (first electrode) and a tubular conductive metal sheet (second electrode) enveloping the metal block at a distance, both the block and the sheet embedded in a body of insulating material, where the insulating material between the block and the sheet forms the dielectric of the integrated capacitor.

Embedding capacitors of a medium-voltage/high-voltage (MV/HV) voltage divider in a body made of a solidified insulating material is a proven method for obtaining a strong, mostly void-free electrical insulation, with the added benefit of mechanical rigidity of the body. When manufacturing such a body, a liquid, viscous, insulating material flows around the electrodes of integrated capacitors in a mold, filling all available space and thus reducing the risk of formation of voids. The insulating material is then caused to cure and thereby solidify. The solidified insulating material forms the body of the sensored insulation plug.

The value of the sensed voltage will normally be transmitted-in analogue or digital form-to the network operator via electronic circuits of a communication network. Those circuits may be comprised in the sensored insulation plug according to the present disclosure. They may, for example, be arranged within the body of the insulation plug or attached to the body of the insulation plug. Such circuits require electrical energy at a low voltage, e. g. at 5 Volt, to operate. Electrical energy is available in the vicinity of the sensored insulation plug, but at much higher voltages and therefore not directly usable to power electronic communication circuits. In a traditional MV/HV switchgear, power at low voltages is not available. So traditionally, for powering electronic communication circuits either low voltage power from an external power supply, e.g. outside the switchgear, had to be brought close to the communication circuit, or a dedicated close-by transformer transformed an elevated voltage down to the low voltages required. These approaches, however, require extra equipment and extra cabling between the power supply and a communication circuit in the sensored insulation plug. The extra equipment and the extra cabling, in turn, require some of the scarce space in the vicinity of the insulation plug, such as in a switchgear housing or in a transformer housing of a power network.

It is, therefore, desirable to reduce the number of external devices, the amount of external cabling and the amount of space occupied by such external devices and cables, while maintaining the ability to transmit the value of the sensed voltage via an external communication network to the network operator. A need exists for a sensored insulation plug that senses the elevated voltage at high accuracy, transmits sensor information towards the network operator, and requires no external power supply.

In some scenarios the power distribution network is utilized for so-called “power line communication” (often also referred to as “PLC”), in which digital or analogue communication signals are superimposed over the elevated voltage and transmitted via power conductors of the network. The signals can be extracted at desired locations in the network. In the context of voltage sensing on a power cable, such power line communication may be used, for example, to transmit the value of the sensed voltage to the network operator. Traditionally, external devices are being used to perform superposition and extraction of power line communication signals. These devices occupy space and require electrical coupling to the power conductor via a coupling device, such as a coupling capacitor. It appears desirable to enable power line communication at the location of a voltage sensor in a manner that reduces the number of coupling devices and requires no additional capacitor for coupling. It appears desirable to enable power line communication at the location of a voltage sensor in a manner that reduces the amount of space occupied by such coupling devices, and the number of electrical connections to the power conductor as well as the associated cost.

Certain methods of identifying and locating failures in a power cable rely on so-called reflectometry, where electromagnetic waves are injected into the power conductor. These waves are partially reflected at locations of the conductor where a mechanical failure has damaged the conductor.

The reflected signals are measured to identify an approximate location and a type of damage. In so-called time-domain reflectometry (“TDR”), a train of fast pulses is emitted by an emitter, coupled into the cable conductor, and the magnitude, duration and shape of the reflected pulses are measured. In contrast thereto, so-called frequency-domain reflectometry (“FDR”) is based on the transmission of a set of stepped-frequency sine waves from an emitter into the cable conductor, and the signal analysis is focused rather on the changes in frequency between the emitted signal and the reflected signal. Reflectometry is normally performed by separate devices which are coupled to the power conductor (e.g. through a coupling capacitor or another coupling device) which emit the pulse or sine waves into the conductor and extract the reflected signal. It appears desirable to enable reflectometry at the location of a voltage sensor, and to enable reflectometry in a manner that reduces the number of coupling devices, the amount of space occupied by such additional coupling devices, and the number of connections to the power conductor.

Partial discharge (“PD”) in MV/HV power conductors is an indication of incipient damage of the conductor's insulation. Partial discharge events cause high-frequency transient current pulses which appear and reappear repeatedly as the voltage sinewave goes through its (positive and negative) peak voltages. The pulses persist for microseconds or fractions thereof and can be detected using different methods. In one method, a PD detector picks up the current signals in the power conductor emanating from a partial discharge. The PD detector may be coupled to the semiconductive layer or the metallic shield of a power cable. Traditionally, dedicated coupling components were used to electrically couple the PD detector to the power conductor or to the semiconductive layer or cable shield. It appears desirable to avoid the use of dedicated coupling components, the additional number of electrical connections and the extra space for accommodating these components.

Where a MV/HV power cable is terminated and connected to a network apparatus it is often desired to provide extra safety for human operators by having a simple indicator to show if elevated voltage is present on the cable and the connection or not. As opposed to a high-accuracy voltage sensor, such an indicator merely senses the presence or the absence of some elevated voltage and often provides a simple visual indication. Such a voltage indicator needs a coupling component for electrical coupling to the high-voltage power conductor. It appears desirable to avoid the use of dedicated coupling components, to avoid having a dedicated electrical connection and to save the extra space for accommodating these coupling components.

For many practical applications it is sufficient to sense the voltage of an MV/HV power conductor at a reduced precision of only 5% of the value of the true elevated voltage, or at an even lower precision. In some scenarios it may be advantageous to have a low-precision (5% accuracy or less precise, i.e. 10% or 20%, for example) voltage sensor in parallel to a high-precision (2% accuracy or more precise, e.g. 1% or even 0.5% accuracy) voltage sensor. Such a low-precision voltage sensor requires a coupling component for electrical coupling to the high-voltage power conductor. Since space is scarce in many network cabinets it would constitute an advantage if a dedicated coupling component were not required, no dedicated electrical connection to the conductor would have to be created and no extra space for accommodating these coupling components were needed.

Portions of a MV/HV power distribution network, such as an individual MV/HV power cable, may be monitored by an electronic monitoring system which comprises sensors in various locations of the network and/or in various locations along the cable. Each sensor is typically connected to a secondary node in which signals from a plurality of sensors are collected. Several secondary nodes communicate data to a primary node which in turn transmits data to a central computing system. Node synchronization signals are exchanged between secondary nodes or between a secondary node and a primary node for the nodes to have a common time base. With the nodes being connected to the power distribution network, the synchronization signals can be exchanged via the conductors of the network. Again, coupling a node synchronization signal from a node into a conductor of the network or extracting a node synchronization signal from the conductor used to require a dedicated coupling component, a dedicated electrical connection to the power conductor and space to accommodate the component. It appears desirable to avoid the use of dedicated synchronization signal coupling components, to avoid having a dedicated electrical connection and to accommodate these coupling components in a space-saving fashion.

Initially, partial discharges occur repeatedly at times when the elevated voltage of the power conductor is at the extremes of its sine wave. Later, when the insulation has suffered some damage, partial discharge occurs closer to the zero crossing of the elevated voltage. In order to assess the severity of damage already caused by partial discharge it is important to determine the exact time when an elevated voltage waveform crosses the zero voltage level. Also, the zero-crossing is important for systems that send digital data over alternating current (AC) conductors. A zero crossing sensor would thus have to be connected to the power conductor in order to detect the zero crossing of the elevated voltage. Typically, installing these sensors requires a dedicated coupling component, a dedicated electrical connection to the power conductor and space to accommodate the component. It appears desirable to avoid the use of dedicated zero-crossing sensor coupling components, to avoid having a dedicated electrical connection and to accommodate these coupling components in a space-saving fashion.

### SUMMARY

In an attempt to address some of these needs, the present disclosure provides a sensored insulation plug for being inserted into a rear cavity of a medium voltage or high-voltage separable connector in a power distribution network of a national grid, and operable to insulate a connection element of the separable connector on an elevated voltage and to sense the elevated voltage, the sensored insulation plug comprising
a) a plug body formed by a solidified insulating material and rotationally symmetric about a plug axis defining axial directions and radial directions orthogonal to the axial directions;
b) an electrically conductive contact piece, mechanically and conductively connectable with the connection element on elevated voltage;
c) a discrete coupling capacitor, operable to
   i) harvest energy from the elevated voltage of the contact piece, and/or
   ii) superimpose a communication voltage signal, such as a power line communication voltage signal, over the elevated voltage of the contact piece, and/or
   iii) extract a communication voltage signal, such as a power line communication voltage signal, from the elevated voltage of the contact piece, and/or
   iv) superimpose a time domain reflectometry signal over the elevated voltage of the contact piece, and extract a time domain reflectometry signal from the elevated voltage of the contact piece, and/or
   v) superimpose a frequency domain reflectometry signal over the elevated voltage of the contact piece, and extract a frequency domain reflectometry signal from the elevated voltage of the contact piece, and/or
   vi) detect a partial discharge signal in the elevated voltage of the contact piece, and/or
   vii) detect the presence or absence of an elevated voltage on the contact piece, and/or
   viii) superimpose a node synchronization signal over the elevated voltage of the contact piece, and/or
   ix) extract a node synchronization signal from the elevated voltage of the contact piece, and/or
   x) sense the elevated voltage at a low accuracy of between 5% and 100% of the true elevated voltage, and/or
   xi) detect a zero crossing of the elevated voltage,
   wherein the coupling capacitor is embedded in the insulating material and comprises a coupling electrode, electrically connected to the contact piece, and an opposed counter electrode,
d) an integrated sensing capacitor, operable as a high-voltage capacitor in a sensing voltage divider for sensing the elevated voltage, the sensing capacitor comprising
   i) a high-voltage electrode, wherein the high-voltage electrode comprises the coupling electrode and the contact piece;
   ii) a tubular sensing electrode, embedded in the insulating material and arranged around an axial section of the high-voltage electrode,
   iii) a dielectric comprising a portion of the insulating material arranged between the sensing electrode and the coupling capacitor.

While the sensing capacitor can be used in a sensing voltage divider to sense the elevated voltage the contact piece, e.g. at an accuracy of 2% or better, the coupling capacitor can be used for one or several or all of the other coupling functions, namely for harvesting energy from the elevated voltage of the contact piece, and/or for superimposing a communication voltage signal, such as a power line communication voltage signal, over the elevated voltage of the contact piece and/or extracting a communication voltage signal from the elevated voltage, and/or for superimposing a time domain reflectometry signal over the elevated voltage of the contact piece, and for extracting a time domain reflectometry signal from the elevated voltage, and/or for superimposing a frequency domain reflectometry signal over the elevated voltage of the contact piece, and for extracting a frequency domain reflectometry signal from the elevated voltage, and/or for superimposing a node synchronization signal over the elevated voltage of the contact piece, and/or for extracting a node synchronization signal from the elevated voltage, and/or for detecting a partial discharge signal in the elevated voltage of the contact piece, and/or for detecting the presence or absence of an elevated voltage on the contact piece, and/or for sensing the elevated voltage at a low accuracy of between 5% and 100% of the true elevated voltage, and/or for detecting a zero crossing of the elevated voltage.

Where the coupling capacitor is used for harvesting energy from the elevated voltage of the contact piece, the harvested energy can be used, for example, to operate electronic circuitry in the sensored insulation plug which processes the voltage sensor data, or to operate other electronic circuitry which transmits processed data to outside the insulation plug, or to sense voltages or to detect signals and events or to superimpose signals or to extract signals.

Where the coupling capacitor is used for harvesting energy the arrangement of the energy-harvesting coupling capacitor within the plug body makes an external power supply and the associated cabling obsolete and saves the space necessary to accommodate such a power supply and such cabling. Also, the insulating material of the plug body can provide proper insulation of the coupling capacitor, making additional insulation for the coupling capacitor unnecessary.

Where the coupling capacitor is used for superimposing a communication voltage signal, such as a power line communication voltage signal, over the elevated voltage of the contact piece and/or extracting a power line communication voltage signal from the elevated voltage, processed voltage sensor data from the electronic circuitry can be transmitted over the power network using known power line communication (“PLC”) technology. Alternatively, or in addition, harvested energy can be used for processing voltage sensor data and/or for transmitting processed voltage sensor data from the electronic circuitry, e.g. in a wireless manner via an antenna to a distant receiver, or via power line communication to a central computing system.

In a preferred embodiment, the discrete coupling capacitor is operable to harvest energy as described above and to superimpose communication voltage signals representing a voltage sensed by the sensing voltage divider over the elevated voltage. The harvested energy can be used to power the sensor electronics and a communication circuit which is operable to superimpose the communication voltage signals over the elevated voltage.

In this embodiment, the twofold function of the coupling capacitor (harvesting energy and superimposing/extracting a communication voltage signal) helps provide a self-sufficient sensor package which can sense voltage and transmit the sensed voltage data to a central computing system without requiring a dedicated external power supply. Such a sensor package could be located anywhere in the network, even in remote locations where external power is not available.

Where the coupling capacitor is used for superimposing a time domain or frequency domain reflectometry signal over the elevated voltage of the contact piece, and for extracting a reflected reflectometry signal (e.g. after a partial reflection at a fault) from the elevated voltage, the sensored insulation plug is useable as an instrument for finding and locating a fault or defect in a conductor of the power distribution network. No additional coupling devices are required, so that the number of external devices is reduced, and no external coupling devices occupy space. As the coupling capacitor is electrically connected to the contact piece on elevated voltage, the coupling capacitor provides an electrical path to the power conductor via which reflectometry signals can be superimposed over the elevate voltage and extracted from it, and no dedicated electrical path for reflectometry signals is required. The number of electrical connections to the power conductor may thereby be reduced. Since the distance range within which faults can be located by reflectometry is limited, certain “remote” regions of the power distribution network may not be covered by existing reflectometry-based fault-locating devices. Placement of an autonomous, self-powered sensored insulation plug according to the present disclosure in such a “remote” region of the network may thus enable fault-locating from a central location, so that repair teams can be deployed earlier and in a more targeted fashion.

Where, in a sensored insulation plug according to the present disclosure, the coupling capacitor is used for superimposing a node synchronization signal over the elevated voltage of the contact piece, and/or for extracting a node synchronization signal from the elevated voltage, no (other) dedicated coupling component for such sync signals is required and no space to accommodate such an additional coupling component is needed. The coupling capacitor provides an electrical path for sync signals into the power conductor and out of it, so that no dedicated (further) electrical connection to the power conductor needs to be made for this purpose.

Where, in a sensored insulation plug according to the present disclosure, the coupling capacitor is used for detecting a partial discharge signal in the elevated voltage, no (other) dedicated coupling component for PD detection is required and no space to accommodate it. The coupling capacitor provides an electrical path for extracting partial discharge signals from the power conductor, so that no further dedicated electrical connection to the power conductor needs to be made for this purpose.

As opposed to voltage sensing, which is meant to measure the magnitude of the elevated voltage on the contact piece to some degree of precision and to yield a numerical value for the voltage, voltage detection merely refers to the determination if an elevated voltage is present or absent on the contact piece. Where, in a sensored insulation plug according to the present disclosure, the coupling capacitor is used for detecting the presence or the absence of the elevated voltage on the contact piece, no (other) dedicated coupling component for voltage detection is required and no space to accommodate it is needed. The coupling capacitor provides an electrical path for detecting the presence or absence of elevated voltage on the power conductor, so that no dedicated electrical connection to the power conductor needs to be made for this purpose. The coupling capacitor may be comprised in a voltage indicator circuit operable to detect the presence or the absence of the elevated voltage on the contact piece. The voltage indicator circuit may, for example, indicate the presence of an elevated voltage if the sensed voltage exceeds a first threshold predefined in the voltage indicator circuit, and may, for example, indicate the absence of an elevated voltage if the sensed voltage does not exceed a second threshold predefined in the voltage indicator circuit.

Where, in a sensored insulation plug according to the present disclosure, the coupling capacitor is used for sensing the elevated voltage at a low accuracy of between 5% and 100% of the true elevated voltage, while the sensing capacitor is used for sensing the elevated voltage at a greater accuracy of between 2% and 0% of the true elevated voltage, the low-accuracy voltage sensor requires no dedicated coupling component for electrical coupling to the high-voltage power conductor. Depending on availability of space in network cabinets it constitutes an advantage if the coupling capacitor is used for connecting a low-accuracy voltage sensor to the conductor, and thereby makes a dedicated coupling component for connecting a low-accuracy voltage sensor obsolete. As electrical coupling to the conductor is achieved through the coupling capacitor, no dedicated further electrical connection to the conductor needs to be created and no extra space for accommodating these coupling components is needed.

In certain embodiments the counter electrode is electrically connected to a low-accuracy voltage sensing circuit which, in conjunction with the coupling capacitor, is operable to sense the elevated voltage at a low accuracy of between 5% and 100% of the true elevated voltage.

Where, in a sensored insulation plug according to the present disclosure, the coupling capacitor is used for detecting a zero crossing of the elevated voltage, a zero crossing sensor requires no (further) dedicated coupling component for electrical coupling to the high-voltage power conductor. Depending on availability of space in network cabinets it constitutes an advantage if, instead of a dedicated separate coupling component, the coupling capacitor is used for connecting a zero-crossing sensor coupling component to the power conductor and make a dedicated coupling component for connecting the zero-crossing sensor obsolete. As electrical coupling to the conductor is achieved through the coupling capacitor, no dedicated electrical connection to the conductor needs to be created and no extra space for accommodating these coupling components is needed.

The present disclosure relates to sensored insulation plugs for use in medium-voltage or high-voltage power distribution networks in which electrical power is distributed over large geographic areas via HV/MV power cables, transformers, switchgears, substations etc. with currents of tens or hundreds of amperes and voltages of tens of kilovolts. The term “medium voltage” or “MV” as used herein refers to AC voltages in the range of 1 kilovolt (kV) to 72 kV rms, whereas the term “high voltage” or “HV” refers to AC voltages of more than 72 kV rms. Medium voltage and high voltage are collectively referred to herein as “elevated voltage”.

Many separable connectors are T-shaped or elbow-shaped. A separable connector as referred to herein usually has a front cavity to receive a protruding portion of a bushing of a switchgear or a transformer, and an opposed rear cavity facilitating access to a connection element, such as a cable lug, on elevated voltage inside the separable connector. The connection element is conductive and is electrically and mechanically connected to the power conductor of the power cable. The connection element can be connected mechanically and electrically, e.g. by a conductive threaded stud, to a conductive element of the bushing, so that power can flow from the power cable through the connection element, the stud and the bushing into the switchgear or transformer. When the separable connector is in use, the connection element is on the elevated voltage of the power conductor of the cable.

Certain separable connectors are described in the European patent application EP 0 691 721 A1. Examples of traditional separable connectors are the 3 M™ 600 Amp T-Bodies 5815 Series from 3M Co., St. Paul, Minnesota, U.S.A., or the “(M) (P) 480 TB separable tee shape connector” of Nexans Network Solutions N. V., Erembodegem, Belgium.

The rear cavity of a separable connector can receive a matching insulation plug to insulate the connection element and to fill the space of the rear cavity to reduce the risk of electrical discharges. Such matching pairs of separable connector and insulation plug are commercially available at moderate cost.

In many cases, the mechanical interface between a separable connector and an insulation plug is governed by de-facto standards. Many of such interfaces conform to an existing standard for bushings, some form a Type C interface as described in the German standards DIN EN 50180 for bushings and DIN EN 50181 for plug-in type bushings, others conform to ANSI/IEEE standard 386. Often, bodies of insulation plugs are slightly larger than the rear cavity, so that after the insulation plug is urged into the rear cavity with some force, the surfaces of plug and cavity are in an intimate surface contact, thus reducing the risk of electrical discharges.

The body of a sensored insulation plug according to the present disclosure is shaped for mating with a rear cavity of a separable connector in the same way as the body of a non-sensored insulation plug. The plug body may be rotationally symmetric about a plug axis. The plug body may, for example, have a frustoconical shape for being inserted into a corresponding frustoconical recess of corresponding shape (the rear cavity) at a rear side of the separable connector, thereby mating the sensored insulation plug with the separable connector.

The plug body may have, in axial directions, a low-voltage end portion and an opposed high-voltage end portion, wherein the high-voltage end portion comprises the contact piece and is, in use, closer to the connection element of the separable connector.

A connection element of a separable connector is electrically connected to the conductor of the power cable terminated by the separable connector and is on elevated voltage when the cable is in use.

Some separable connectors comprise a connection element such as a cable lug, attached to the end of the central conductor of the power cable and protruding into a space between the front cavity and the rear cavity. The protruding portion of the connection element usually has an aperture or a thread for attachment to a stud or screw which connects the connection element electrically and mechanically, e.g. with a conductor of a bushing.

The connection element of the separable connector serves to electrically and mechanically connect the power cable and the separable connector to a bushing. The high-voltage electrode of the sensing capacitor of the sensored insulation plug as described herein is—when in use—directly electrically connected to the connection element, so that a voltage sensor based on a voltage divider comprising the sensing capacitor in its high-voltage portion can sense the elevated voltage of the connection element and thereby the elevated voltage of the power cable conductor, after connection of the power cable to the bushing.

As used herein, “sensing at a high accuracy” refers to a higher-precision measurement of the elevated voltage, such as 2% precision or better, or 1% precision or better. “Sensing” is different from “detecting” which refers to identifying presence or absence of an elevated voltage, and from “sensing at a low accuracy”, which refers to a lower-precision measurement of the elevated voltage, such as 5% precision or 10% precision, or at an even lower precision. An expression like “5% precision” refers to the sensed value being within 5% from the true value, e.g. of the elevated voltage.

The sensing capacitor is operable as a high-voltage capacitor in the sensing voltage divider for sensing the elevated voltage with a higher degree of precision. The sensing voltage divider may be a capacitive voltage divider. The connection element of a separable connector is electrically connected to the sensing voltage divider such that the sensing voltage divider can sense the elevated voltage of the connection element. For that purpose, the connection element on elevated voltage is electrically connected to the high-voltage electrode of the sensing capacitor in the sensored insulation plug which in turn is operable as a high-voltage capacitor in the sensing voltage divider for sensing the elevated voltage. For high-accuracy voltage sensing the capacitance of the sensing capacitor is preferably between 10 picofarad (pF) and 50 picofarad.

The contact piece of a sensored insulation plug according to the present disclosure is arranged in the high-voltage end portion of the plug body, as described below. A portion of the contact piece is exposed and externally accessible for facilitating establishing an electrical connection to the connection element of the separable connector.

In use, the contact piece may be not only electrically, but also mechanically connected to the connection element of the separable connector. This mechanical connection advantageously is an electrically conductive connection. The mechanical connection may be a direct mechanical connection, i.e. a portion of the contact piece is mechanically connected to the connection element without any intermediate element between them, i.e. via a surface contact.

Alternatively, this connection may be an indirect mechanical connection, i.e. in use a portion of the contact piece may be connected to the connection element via an intermediate element, which is electrically conductive. The sensored insulation plug may thus further comprise an intermediate element which is operable to mechanically and electrically connect the contact piece with the connection element.

The contact piece, or an engagement portion of the contact piece, may comprise a recess to connectingly engage a stud that is connected to the connection element of the separable connector. The contact piece, or an engagement portion of the contact piece, may comprise an internal or external thread to connectingly and threadedly engage a threaded stud that is connected to the connection element of the separable connector.

The high-voltage electrode and the sensing electrode are the electrodes of the sensing capacitor. In a sensored insulation plug according to the present disclosure the high-voltage electrode comprises the coupling electrode of the coupling capacitor and the contact piece. The coupling electrode may be arranged in the coupling capacitor, e.g. in a body of the coupling capacitor, and the sensing electrode may be arranged outside the coupling capacitor. In such embodiments the dielectric of the sensing capacitor may comprise a portion of the insulating material arranged between the sensing electrode and the coupling capacitor. The dielectric of the sensing capacitor may further comprise a portion of a dielectric of the coupling capacitor. This latter portion may be arranged inside the coupling capacitor, e.g. in a body of the coupling capacitor.

In certain embodiments the coupling electrode is flat and oriented parallel to a geometric plane extending in radial directions. In other words, the coupling electrode lies in a geometric plane, and a normal on the geometric plane is parallel to axial directions. Discrete capacitors having a flat coupling electrode are commercially available at reasonable cost. The orientation of the coupling electrode can help provide for a shorter overall design of the sensored insulation plug.

Generally, the coupling electrode may have a flat major surface facing, or contacting, a dielectric of the coupling capacitor. In certain embodiments a surface normal of the flat major surface is oriented parallel to the plug axis.

Generally, the shape and orientation of the coupling electrode are not critical. For adequate voltage sensing, a shape and an orientation are preferable which allow the coupling electrode and the sensing electrode to form the electrodes of the sensing capacitor.

The high-voltage electrode comprises the coupling electrode of the coupling capacitor and the contact piece. It may further comprise a high-voltage electrode extension portion, electrically connected to the coupling electrode. The high-voltage electrode extension portion may be arranged outside of the coupling capacitor. The high-voltage electrode extension portion may be embedded in the insulating material. In preferred embodiments the high-voltage electrode is embedded in the insulating material.

In certain embodiments the high-voltage electrode is an assembly consisting of the coupling electrode and the contact piece.

In certain preferred embodiments, the tubular sensing electrode is shaped and arranged such as to be generally rotationally symmetric about the plug axis of the sensored insulation plug. The high-voltage electrode may be shaped and arranged such as to be generally rotationally symmetric about the plug axis of the sensored insulation plug. Independent of their shapes, the high-voltage electrode and the sensing electrode may be arranged coaxially, or concentrically with each other. Specifically, the tubular sensing electrode may be arranged coaxially around an axial section of the high-voltage electrode.

The tubular sensing electrode is arranged around an axial section of the high-voltage electrode. It may be arranged around an axial section of the coupling electrode and/or around an axial section of the contact piece. It may be arranged around an axial section of the coupling capacitor or around the entire coupling capacitor. It may be arranged around the entire contact piece. The sensing electrode being arranged around the high-voltage electrode implies that the sensing electrode, or at least an axial section of the sensing electrode, is arranged radially outward from the high-voltage electrode and surrounds at least an axial section of the high-voltage electrode. The sensing electrode, or at least an axial section of the sensing electrode, may be arranged radially outward from the coupling capacitor and may surround at least an axial section of the coupling capacitor. The sensing electrode, or at least an axial section of the sensing electrode, may be arranged radially outward from the contact piece and may surround at least an axial section of the contact piece.

In certain embodiments the plug body is rotationally symmetric about a plug axis, and the high-voltage electrode—which comprises the coupling electrode of the coupling capacitor and the contact piece—and the sensing electrode may be arranged coaxially around the plug axis, and the sensing electrode may be arranged coaxially around the high-voltage electrode. The coaxial arrangement may help to avoid concentration of electrical field lines and to provide for a reduced risk of electrical discharges. The coaxial arrangement of the sensing electrode around the high-voltage electrode may result in a space-saving arrangement of the sensing capacitor and a more even distribution of the electrical field with less risk of electrical discharges.

The expression “embedded in the plug body” as used herein refers to being surrounded completely by portions of the plug body, e.g. by portions of the insulating material forming the plug body. In particular, an electrode is considered embedded in the plug body if the plug body is cast or molded around the electrode. In a particular aspect, an element of the sensored insulation plug may be considered embedded in the plug body if a major portion, e.g. more than 90% or more than 95%, of its exterior surface is in surface contact with the solidified insulating material. Surface contact, however, is not a prerequisite for being considered “embedded”, as an embedded element may, for example, be arranged in a cavity of the plug body without being in surface contact with the solidified insulating material.

The coupling capacitor is embedded in the insulating material forming the plug body. The high-voltage electrode of the sensing capacitor is embedded in the plug body. A portion of the embedded high-voltage electrode, or the entire embedded high-voltage electrode, may be in surface contact with the insulating material of the plug body.

The sensing electrode of the sensing capacitor is embedded in the plug body. The entire sensing electrode, or a portion of the embedded sensing electrode, may be in surface contact with the insulating material of the plug body.

The coupling capacitor is a discrete capacitor that can be operated at medium voltages or high voltages. In order to perform its coupling functions (i.e. to facilitate to superimpose/extract signals, detect partial discharge signals and zero crossing, sense voltage at low accuracy, detect absence or presence of elevated voltage), it preferably has a comparatively high capacitance, such as a capacitance of 100 picofarad (pF) or more, of 500 picofarad (pF) or more, such as between 500 pF and 1000 pF, or of greater than 1 nanofarad (nF). A greater capacitance generally results in the ability to harvest more energy from the elevated voltage and/or can facilitate impedance matching with certain circuits connected to the coupling capacitor, such as reflectometry circuits, PLC circuits, or communication superposition circuits, as explained below. Capacitors of less than 100 pF are currently not perceived as useable as coupling capacitors according to the present disclosure, because they may not be able to harvest a sufficient amount of energy within a reasonable time, or do not provide efficient coupling with the power conductor. Hence in certain embodiments the coupling capacitor has a capacitance of 100 picofarad or more, and in other embodiments, or the coupling capacitor has a capacitance of 500 picofarad or more. In certain of these embodiments the coupling capacitor has a capacitance of between about 500 picofarad and about 1000 picofarad.

In certain embodiments the coupling capacitor is a ceramic capacitor. In certain embodiments the coupling capacitor is a single-layer capacitor, such as a single-layer ceramic capacitor. Single-layer capacitors having both a high voltage withstand and a high capacitance are commercially available at reasonable cost. Due to the geometry of their electrodes (flat, opposed and parallel to each other) the electrical field between the coupling electrode and the sensing electrode is less disturbed than in scenarios in which the coupling capacitor is a multi-layer capacitor. The geometry of the electrodes of single-layer capacitors can generally result in a more even distribution of electric field lines and an associated reduced risk of electrical discharges.

Although it may be preferred for the coupling capacitor to be a single-layer capacitor, in certain other embodiments the coupling capacitor is a multi-layer capacitor, e.g. a multi-layer ceramic capacitor. Although the electrical field between the coupling electrode and the sensing electrode may be disturbed, the sensing electrode and the coupling electrode can usually still form a sensing capacitor of an adequate capacitance for precise voltage sensing.

In certain of these embodiments the coupling electrode and the counter electrode are arranged at opposed end portions of the coupling capacitor. The coupling electrode and the counter electrode may be flat electrodes, oriented parallel to each other and facing each other. A coupling capacitor dielectric material may be arranged between the coupling electrode and the counter electrode.

Single layer capacitors can provide both a high voltage withstand, making them suitable for use with elevated voltages, and a high capacity of 100 picofarad or more, making them suitable for use as a coupling capacitor in the present sensored insulation plug.

In specific embodiments the coupling capacitor is a ceramic single-layer capacitor of a cuboid shape, with the coupling electrode and the counter electrode being arranged at opposed flat parallel end faces of the cuboid shape. In other specific embodiments the coupling capacitor is a ceramic single-layer capacitor and has a cylindrical shape, with the coupling electrode and the counter electrode being arranged at the opposed flat parallel end faces of the cylindrical shape. The coupling capacitor of cylindrical shape may be arranged in the plug body coaxially with the plug axis.

The coupling capacitor is electrically connected with the contact piece on elevated voltage when in use, therefore the coupling capacitor preferably has a voltage withstand of at least one kilovolt (1 kV), of at least 10 kV, or of at least 50 kV. The choice of voltage withstand will depend, inter alia, on the expected magnitude of the elevated voltage.

Discrete capacitors of suitable capacitances for use as a coupling capacitor for medium or high voltages are commercially available, e.g. from TDK (tdk.com) or from Vishay (vishay.com).

In a sensored insulation plug according to the present disclosure the counter electrode of the coupling capacitor may be connected to one or more electrical circuits which perform, in conjunction with the coupling capacitor, the respective function (such as energy harvesting, superimposing and/or extracting signals, detecting partial signals and/or presence and absence of elevated voltage or zero crossing, or low-accuracy voltage sensing, as described herein).

Thus, in certain embodiments the counter electrode is electrically connected to a harvesting circuit which, in conjunction with the coupling capacitor, is operable to harvest energy from the elevated voltage of the contact piece. The harvesting circuit may further comprise a rectifier, such as a Graetz rectifier, and a capacitor to store harvested energy. In certain embodiments the harvesting circuit provides the harvested energy to a processor. The processor may be operable to generate communication voltage signals representing the magnitude of the elevated voltage sensed by the sensing voltage divider.

In certain embodiments the counter electrode is electrically connected to a communication circuit which, in conjunction with the coupling capacitor, is operable to generate communication signals and superimpose the communication signals over the elevated voltage of the contact piece, and/or is operable to extract communication signals from the elevated voltage of the contact piece. The communication circuit may comprise a frequency generator and a processor, operable to generate communication signals. The communication circuit may comprise a bandpass filter and a receiver, operable to extract communication signals. In certain of these embodiments the communication signals are power line communication signals. In certain of those embodiments the power line communication signals comply with the IEEE 1901 standard, in particular with the IEEE 1901.2 low-frequency standard for long-distance smart grids, or with the IEEE 1905 standard, each in its respective version as in force on 28 Mar. 2023. The communication circuit may thus be a power line communication circuit.

The counter electrode may be connected to a harvesting circuit as described above and to a communication circuit as described above. It may be sequentially connected to a harvesting circuit and to a communication circuit in a switched or multiplexed manner as described below.

In certain embodiments the counter electrode is electrically connected to a reflectometry circuit which, in conjunction with the coupling capacitor, is operable to generate reflectometry signals and superimpose the reflectometry signals over the elevated voltage of the contact piece. The reflectometry circuit is also operable to extract reflectometry signals from the elevated voltage of the contact piece. The reflectometry circuit may comprise a frequency generator and a processor, operable to generate reflectometry signals for superposition over the elevated voltage. The reflectometry circuit may comprise a bandpass filter and a receiver, e.g. a receiver comprising an analogue-digital converter, operable to extract the reflectometry signals superimposed on the elevated voltage and subsequently reflected in the conductor. Reflectometry signals may be time domain reflectometry signals or frequency domain reflectometry signals. The reflectometry circuit may be, may comprise, or may be comprised in a time domain reflectometer (TDR). The reflectometry circuit may be, may comprise, or may be comprised in a frequency domain reflectometer (FDR).

The counter electrode may be connected to a harvesting circuit as described above and to a reflectometry circuit as described above, either simultaneously or sequentially, e.g. via a switch or via a multiplexer. It may be connected to a harvesting circuit as described above and to a reflectometry circuit as described above and to a communication circuit as described above, either simultaneously or sequentially, e.g. via a switch or via a multiplexer.

In certain embodiments the counter electrode is electrically connected to a partial discharge detection circuit which, in conjunction with the coupling capacitor, is operable to detect partial discharge signals, and/or is operable to extract a partial discharge signal in the elevated voltage of the contact piece. A partial discharge generates a short peak of extra current (with a total charge of a few pico Coulomb) which is superimposed over the current through the power conductor. This small signal in the current through the conductor can be detected as a peak in the voltage of the counter electrode, the size of the peak being dependent on the capacitance of the coupling capacitor. The partial discharge detection circuit may be operable to detect timing and magnitude of the peak. The partial discharge detection circuit may comprise a high-pass filter and a detector, operable to extract the partial discharge detection signals from the elevated voltage. Alternatively, the voltage can be digitally sampled at a high rate, with the waveform recorded at that high rate. Hence the partial discharge detection circuit may comprise a digital sampling device and a high-rate waveform recording device, operable to detect a partial discharge signal in the elevated voltage of the contact piece.

In certain embodiments the counter electrode is electrically connected to a node synchronization circuit which, in conjunction with the coupling capacitor, is operable to generate node synchronization signals and superimpose the node synchronization signals over the elevated voltage of the contact piece, and/or is operable to extract node synchronization signals from the elevated voltage of the contact piece. The node synchronization circuit may comprise a processor, operable to generate node synchronization signals.

In certain embodiments the counter electrode is electrically connected to a zero crossing detection circuit which, in conjunction with the coupling capacitor, is operable to detect a zero crossing of a waveform of the elevated voltage on the contact piece. The zero crossing detection circuit may, for example, comprise a comparator and/or an analog-to-digital converter, operable to detect a zero crossing of the voltage of the counter electrode which corresponds to a zero crossing of the elevated voltage.

The counter electrode may be connected to a harvesting circuit as described above, and/or to a reflectometry circuit as described above, and/or to a reflectometry circuit as described above, and/or to a partial discharge detection circuit as described above, and/or to a node synchronization circuit, and/or to a zero crossing detection circuit, either simultaneously or sequentially, e.g. via a switch or via a multiplexer.

Harvested energy is preferably used to power one or more analogue-to-digital (A/D) converters to digitize the signal voltage of the sensing voltage divider. In certain embodiments, at least a portion of the harvested energy is used to transmit at least data representing the signal voltage to an outside of the sensored insulation plug, such as to a receiving node of a communication network, e.g. of the network operator. Even some low-power A/D converters and low-power transmitters require some tens of milliwatts (mW) or some hundreds of mW to operate. The capacitance of the coupling capacitor and the power consumption of the A/D converters, the transmitters and optionally of other electronic components thus need to be balanced against each other and a selection needs to be made, depending on the application needs. The geometric size of the coupling capacitor will need to be balanced against the space available in the insulation plug, against the capacitance required for harvesting an adequate amount of power, the capacitance required for performing the coupling functions, against the need for sufficient electrical insulation, and potentially against other factors.

For enabling such energy harvesting, the coupling electrode of the coupling capacitor is electrically connected to the contact piece on elevated voltage. The counter electrode of the coupling capacitor may be electrically connected to a harvesting circuit, comprised in the sensored insulation plug. Hence in certain embodiments in which the discrete coupling capacitor of the sensored insulation plug is operable to harvest energy from the elevated voltage of the contact piece, the sensored insulation plug further comprises a harvesting circuit, electrically connected to the counter electrode, and operable to harvest electrical energy from the elevated voltage. In certain embodiments in which the discrete coupling capacitor of the sensored insulation plug is operable to harvest energy from the elevated voltage of the contact piece, the sensored insulation plug further comprises a harvesting circuit, electrically connected to the counter electrode and operable, in conjunction with the coupling capacitor, to harvest electrical energy from the elevated voltage.

In certain embodiments the harvesting circuit is arranged outside the plug body, e. g. remote from the plug body or in the vicinity of the plug body. It may, for example, be arranged in or on an end cap covering a low-voltage end portion of the sensored insulation plug. The harvesting circuit may be arranged, for example, on a circuit board attached to the plug body, e.g. attached to an outer surface of the plug body. An attachment of the harvesting circuit to the plug body may save space and avoid the need to use cables or wires of certain lengths for connecting the harvesting circuit to the coupling capacitor. In such embodiments the counter electrode of the coupling capacitor may be electrically connected to the harvesting circuit via a harvesting wire or a harvesting cable. Hence generally the sensored insulation plug described herein may further comprise an end cap attached to a low-voltage end portion of the plug body, wherein the harvesting circuit is arranged in the end cap.

In certain alternative embodiments the harvesting circuit is arranged in the plug body. It may be arranged, for example, on a circuit board within the plug body, such as on a circuit board embedded in the plug body. In these embodiments the counter electrode of the coupling capacitor may be electrically connected to the harvesting circuit via a harvesting wire embedded at least partially in the insulating material of the plug body. An arrangement inside the plug body is a particularly space-saving arrangement of the harvesting circuit, which may also protect the harvesting circuit against certain mechanical and environmental impacts. An arrangement inside the plug body may also help keep conductive connections shorter and thereby reduce ohmic losses.

In certain embodiments the harvesting circuit comprises a storage capacitor for storing electrical energy harvested from the elevated voltage.

While the elevated voltage is an AC voltage, energy can more easily be harvested and stored as DC voltage and DC currents. Also, where harvested energy is used to power electric or electronic components, many such components require a DC power supply. Therefore, in certain embodiments of a sensored insulation plug according to the present disclosure the harvesting circuit comprises a rectifier, connected to the counter electrode, for rectifying a voltage of the counter electrode.

In certain of these embodiments the harvesting circuit further comprises a storage capacitor for storing harvested electrical energy. Storing the harvested energy facilitates multiplexing between harvesting time slots and PLC or wireless communication time slots, as described below in more detail.

The sensored insulation plug according to the present disclosure may comprise a dedicated signal processing circuit for processing the signal voltage of the sensing voltage divider. Processing may make the signal voltage comply with input requirements of external devices such as remote termination units (RTUs) or with input requirements of transmission circuits such as, for example, a PLC circuit or a wireless transmission circuit as described below. The signal voltage is the voltage of the signal contact which varies proportionally with the elevated voltage. Where the high-voltage portion of the sensing voltage divider consists only of the sensing capacitor, the signal voltage is the voltage of the sensing electrode. In certain embodiments the signal voltage is processed, e.g. it is digitized, normalized, or filtered. The signal processing circuit is operable to process the signal voltage. It may be connected to the signal contact, or it may be connected to the sensing electrode.

Hence in certain embodiments the discrete coupling capacitor of the sensored insulation plug is operable to harvest energy from the elevated voltage, wherein the sensored insulation plug comprises a harvesting circuit, electrically connected to the coupling capacitor and operable to harvest energy from the elevated voltage, and further comprises a signal processing circuit, electrically connected to the sensing electrode, and operable to process a signal voltage of the sensing electrode, wherein the signal processing circuit is electrically connected to the harvesting circuit such that the signal processing circuit receives electrical energy from the harvesting circuit.

The signal processing circuit is preferably powered by electrical energy harvested by the harvesting circuit from the elevated voltage. Alternatively, it may be provided externally with power.

The signal processing circuit may comprise an analogue-to-digital converter (“ADC”) for converting an analogue signal voltage into digital data representing the signal voltage or for converting a processed analogue signal voltage into digital data representing the processed signal voltage. Hence generally, the signal processing circuit may comprise an analogue-to-digital converter for digitizing the signal voltage.

The coupling capacitor may be operable to superimpose a communication voltage signal, such as a power line communication (“PLC”) signal, over the elevated voltage. The communication voltage signal may be, for example, a data signal representing the signal voltage of the sensing voltage divider. The communication voltage signals can be transmitted via the contact piece of the sensored insulation plug, the connection element of a separable connector and a conductor of a cable terminated by the separable connector towards a receiving node in a communication network, e.g. of the network operator. Accordingly, the coupling capacitor may be suitable for superimposing a communication voltage signal over the elevated voltage of the contact piece.

For enabling such power line communication, the coupling electrode of the coupling capacitor is electrically connected to the contact piece, and the counter electrode of the coupling capacitor may be electrically connected to a power line communication circuit. The PLC circuit comprises electronic circuitry for powerline communication, in particular for superimposing a communication voltage signal over the elevated voltage, via the coupling capacitor and for extracting a communication voltage signal from the elevated voltage, and thereby transmitting and receiving communication voltage signals (such as data signals representing the signal voltage of the sensing voltage divider) into the elevated voltage and via a cable conductor towards a receiving node of a communication network, e.g. of the network operator.

Hence generally, in certain embodiments of the sensored insulation plug described herein, the sensored insulation plug further comprises a powerline communication circuit, electrically connected to the coupling capacitor, and operable to superimpose, via the coupling capacitor, a communication voltage signal over the elevated voltage, and/or operable to extract, via the coupling capacitor, a communication voltage signal from the elevated voltage.

Where the sensored insulation plug comprises a harvesting circuit, the powerline communication circuit may be electrically connected to the harvesting circuit such that the powerline communication circuit receives electrical energy from the harvesting circuit. Alternatively, it may be externally powered.

In certain embodiments the PLC circuit is not comprised in the sensored insulation plug. It may be arranged outside the plug body, e. g. remote from the sensored insulation plug. It may, for example, be arranged in or on an end cap covering a low-voltage end portion of the plug body. In such embodiments the counter electrode of the coupling capacitor may be electrically connected to the PLC circuit via a PLC wire or a PLC cable.

In certain other embodiments the PLC circuit is comprised in the sensored insulation plug. It may be arranged, for example, in the plug body. It may be embedded in the plug body. It may be arranged, for example, on a circuit board within the plug body or on a circuit board attached to the plug body, e.g. to an outer surface of the plug body. In these embodiments the counter electrode of the coupling capacitor may be electrically connected to the PLC circuit via a PLC wire embedded at least partially in the insulating material of the plug body.

The discrete coupling capacitor can work for power line communication both ways. Hence it may be also operable to pick up communication voltage signals superimposed over the elevated voltage of the contact piece, i.e. it may be operable to extract a communication voltage signal from the elevated voltage. With the counter electrode of the coupling capacitor being electrically connectable to the PLC circuit, e.g. a PLC circuit arranged in the plug body or attached to the body of the sensored insulation plug, the PLC circuit may be operable to receive communication voltage signals from a transmitting node of the network operator's communication network. The PLC circuit may be operable to receive communication voltage signals (such as data signals representing firmware updates for a microcontroller in the PLC circuit or representing updated calibration values or updated encryption/decryption keys) via a power cable conductor on elevated voltage from a transmitting node of a communication network, e.g. of the network operator. Accordingly, the coupling capacitor may be operable to extract a communication voltage signal from the elevated voltage of the contact piece.

The coupling capacitor may not be useable for harvesting energy and for another coupling function, such as powerline communication, at the same time. The sensored insulation plug may therefore comprise electronic multiplexing circuitry for defining harvesting time slots and time slots for one or more of the other coupling functions described above, such as superposition or extraction of signals, detection or sensing of elevated voltage (“SEDS functions”). These latter time slots will be referred to herein also as “SEDS time slots”.

During a harvesting time slot the multiplexing circuitry may cause the coupling electrode of the coupling capacitor to be electrically connected to the high-voltage electrode, and the counter electrode of the coupling capacitor to be electrically connected to the harvesting circuit and optionally disconnected from the circuits operable to perform any one of the SEDS functions (“SEDS circuits”). During a harvesting time slot, the multiplexing circuitry may cause the coupling electrode of the coupling capacitor to be electrically connected to the high-voltage electrode, and the counter electrode of the coupling capacitor to be electrically connected to the harvesting circuit and optionally disconnected from the SEDS circuits and the wireless communication circuit described above.

During an SEDS time slot the multiplexing circuitry may cause the coupling electrode of the coupling capacitor to be electrically connected to the high-voltage electrode, and the counter electrode of the coupling capacitor to be electrically connected to one or more of the SEDS circuits and optionally disconnected from the harvesting circuit described above.

In addition to being operable to perform one or more of the coupling functions, the sensored insulation plug of the present disclosure may be adapted to transmit communication voltage signals (e.g. data signals representing the signal voltage of the sensing voltage divider) in a wireless manner.

Where the sensored insulation plug comprises a harvesting circuit, operable, in conjunction with the coupling capacitor, to harvest electrical energy from the elevated voltage, it may further comprise a wireless communication circuit operable to generate and wirelessly transmit a communication voltage signal to outside the sensored insulation plug. The wireless communication circuit may be electrically connected to the harvesting circuit such that the wireless communication circuit receives electrical energy from the harvesting circuit. Energy harvested using the coupling capacitor may thus be used to supply electric energy to the wireless communication circuit.

The wireless communication circuit may be further operable to wirelessly receive a communication voltage signal from outside the sensored insulation plug.

For the purpose of wirelessly transmitting or receiving, a sensored insulation plug according to the present disclosure comprising a wireless communication circuit may further comprise an antenna connected to the wireless communication circuit and operable to receive and to transmit communication voltage signals. The communication voltage signals can be transmitted, for example, via the antenna wirelessly towards a receiving node in a communication network, e. g. a communication network of the network operator.

A wireless communication circuit may be arranged in the plug body. Alternatively, it may be arranged outside of the plug body. The wireless communication circuit is operationally connected with the antenna. It comprises electronic circuitry for transmitting communication voltage signals (e.g. a data signal representing the signal voltage of the sensing voltage divider) via the antenna towards a receiving node of a communication network, e.g. of the network operator, and optionally for receiving communication voltage signals (e.g. a synchronization signal) via the antenna from a transmitting node of the communication network.

The wireless communication circuit comprises electronic circuitry for transmitting communication voltage signals (e.g. data signals representing the signal voltage of the sensing voltage divider) wirelessly towards a receiving node of a communication network, e.g. of the network operator.

In certain embodiments the wireless communication circuit is arranged outside the plug body, e.g. remote from the plug body. It may, for example, be arranged in or on an end cap covering a low-voltage end portion of the plug body. In such embodiments the counter electrode of the coupling capacitor may be electrically connected to the wireless communication circuit via a connection wire or a connection cable.

In certain other embodiments the wireless communication circuit is arranged in the plug body. It may be arranged, for example, on a circuit board within the plug body. Alternatively, the wireless communication circuit is arranged on a circuit board attached to the plug body, e.g. to an outer surface of the plug body. In these embodiments the counter electrode of the coupling capacitor may be electrically connected to the wireless communication circuit via a connection wire embedded at least partially in the insulating material of the plug body.

Although the coupling capacitor may be operable for harvesting energy and wireless communication at the same time, it may be advantageous in certain scenarios to perform harvesting and wireless communication at separate times. Multiplexing circuitry may thus be operable to define harvesting time slots and wireless time slots. During a wireless time slot, the multiplexing circuitry may, for example, cause the coupling electrode of the coupling capacitor to be electrically connected to the high-voltage electrode, and the counter electrode of the coupling capacitor to be electrically connected to the wireless communication circuit and optionally disconnected from the harvesting circuit described above.

During a harvesting time slot the multiplexing circuitry may, for example, cause the coupling electrode of the coupling capacitor to be electrically connected to the high-voltage electrode, and the counter electrode of the coupling capacitor to be electrically connected to the harvesting circuit and optionally disconnected from the wireless communication circuit. During a harvesting time slot, the multiplexing circuitry may cause the coupling electrode of the coupling capacitor to be electrically connected to the high-voltage electrode, and the counter electrode of the coupling capacitor to be electrically connected to the harvesting circuit and optionally disconnected from the wireless communication circuit and optionally disconnected from the SEDS circuits described above.

The coupling capacitor may be operable to perform energy harvesting and one or more of the SEDS functions defined above. Both the integrated sensing capacitor and the discrete coupling capacitor are comprised in the sensored insulation plug described herein. However, not all remaining elements of the sensing voltage divider and of the harvesting and SEDS functions setup may be comprised in the sensored insulation plug. In certain embodiments, an energy harvesting electronic circuit, to which the coupling capacitor is connected, is not comprised in the sensored insulation plug, while a powerline communication electronic circuit, to which the coupling capacitor is connected, is comprised in the sensored insulation plug. In certain other embodiments, the energy harvesting electronic circuit is comprised in the sensored insulation plug, while none of the SEDS circuits is comprised in the sensored insulation plug. In certain other embodiments, neither the harvesting circuit nor any of the SEDS circuits is comprised in the sensored insulation plug.

An energy harvesting electronic circuit may be arranged on a printed circuit board. Any SEDS circuit, or all SEDS circuits, may be arranged on a printed circuit board. In certain preferred embodiments, both the harvesting circuit and the SEDS circuits are comprised in the sensored insulation plug. These electronic circuits may be arranged in the plug body of the sensored insulation plug or they may be attached to the plug body, as will be detailed below. A printed circuit board on which the harvesting circuit is arranged may be attached to the plug body. A printed circuit board on which one, several, or all of the SEDS circuits are arranged may be attached to the plug body. A printed circuit board on which the harvesting circuit and one, several or all of the SEDS circuits are arranged may be attached to the plug body.

The sensing capacitor of the sensored insulation plug described herein is suitable for sensing the elevated voltage at a high precision of two percent or better. It is operable as a high-voltage capacitor in a sensing voltage divider for sensing the elevated voltage. The sensing voltage divider may be adapted, e.g. by selecting a low-voltage capacitor of suitable capacitance, such that the dividing ratio is adequate to provide, for an elevated voltage of 50 kV, a signal voltage that can be processed by standard electronic circuitry, e.g. a signal voltage of a few Volt, e.g. 5 Volt. Also, it is desired to minimize parasitic capacitances. Hence preferably, the sensing capacitor has a capacitance of between about 10 pF and about 50 pF. The desired capacitance of the sensing capacitor is thus considerably different from the desired capacitance of the coupling capacitor (which is 100 pF or more). For this reason, the sensored insulation plug of the present disclosure comprises two separate capacitors: the sensing capacitor for high-precision voltage sensing and the coupling capacitor for energy harvesting or one of the other coupling functions. These two capacitors share the coupling electrode, connected to the contact piece, as the “source” of the elevated voltage.

The sensing capacitor of the present sensored insulation plug is designed for sensing the elevated voltage to a great precision, e.g. at a precision of 2% or 1% or better. To obtain such great precision, the dividing ratio of the sensing voltage divider must be precisely known. Certain methods of determining the dividing ratio require precise knowledge of the true capacitance of the sensing capacitor and of the true capacitance(s) of the low-voltage capacitor(s) at the time of performing the voltage sensing. The true capacitance of the sensing capacitor is essentially its nominal capacitance, which is modified by certain variations, such as, for example, variations introduced by ageing effects or temperature effects on the dielectric, geometric variations of the distance between the electrodes, etc.

As opposed to the sensing capacitor, precise knowledge of the true capacitance of the coupling capacitor and its variations is not critical for the performance of the coupling capacitor in energy harvesting or any other of the coupling functions. Hence a discrete coupling capacitor that has a rather coarse precision rating can be used, such as 5% or even 10%.

The coupling capacitor of the sensored insulation plug described herein is coupled to the elevated voltage to facilitate, in conjunction with other elements, performing at least one, and optionally a plurality, and optionally all, of the following functions:
i) harvest energy from the elevated voltage of the contact piece,
ii) superimpose a communication voltage signal, such as power line communication voltage signal, over elevated voltage,
iii) extract a communication voltage signal, such as a power line communication voltage signal, from the elevated voltage,
iv) superimpose a time domain reflectometry signal over the elevated voltage of the contact piece, and extract a time domain reflectometry signal from the elevated voltage of the contact piece,
v) superimpose a frequency domain reflectometry signal over the elevated voltage of the contact piece, and extract a frequency domain reflectometry signal from the elevated voltage of the contact piece,
vi) detect a partial discharge signal in the elevated voltage of the contact piece,
vii) detect the presence or absence of an elevated voltage on the contact piece,
viii) superimpose a node synchronization signal over the elevated voltage of the contact piece,
ix) extract a node synchronization signal from the elevated voltage of the contact piece,
x) sense the elevated voltage at a low accuracy of between 10% and 100% of the true elevated voltage,
xi) detect a zero crossing of the elevated voltage.

These functions i)-xi) are collectively referred to as “coupling functions” herein.

The coupling capacitor is operable to perform one or more or all of the coupling functions. The coupling capacitor may be operable to perform the function by virtue of being connected to an electronic circuit which performs the function. The coupling capacitor is thus operable, in conjunction with a respective electronic circuit to perform the respective function. For example, the coupling capacitor may be operable to harvest energy in conjunction with a harvesting circuit, and/or it may be operable to superimpose a powerline communication voltage signal over the elevated voltage in conjunction with a communication superposition circuit. The respective circuit(s), such as the harvesting circuit or the communication superposition circuit may be comprised in the sensored insulation plug, or it may not be comprised in the sensored insulation plug.

Therefore, in certain embodiments of the sensored insulation plug described herein,
i) wherein the coupling capacitor is operable to harvest energy from the elevated voltage of the contact piece, the sensored insulation plug further comprises a harvesting circuit, electrically connected to the coupling capacitor and operable, in conjunction with the coupling capacitor, to harvest energy from the elevated voltage of the contact piece; and/or
ii) wherein the coupling capacitor is operable to superimpose a communication voltage signal, such as a power line communication voltage signal, over the elevated voltage of the contact piece, the sensored insulation plug further comprises a communication superposition circuit, electrically connected to the coupling capacitor and operable to generate communication signals and, in conjunction with the coupling capacitor, to superimpose the communication signals over the elevated voltage of the contact piece; and/or
iii) wherein the coupling capacitor is operable to extract a communication voltage signal, such as a power line communication voltage signal, from the elevated voltage of the contact piece, the sensored insulation plug further comprises a communication extraction circuit, electrically connected to the coupling capacitor and operable, in conjunction with the coupling capacitor, to extract communication signals from the elevated voltage of the contact piece; and/or
iv) wherein the coupling capacitor is operable to superimpose a time domain reflectometry signal over the elevated voltage of the contact piece, and is operable to extract a time domain reflectometry signal from the elevated voltage of the contact piece (such as a signal formed by partial reflection of the superimposed signal), the sensored insulation plug further comprises a time domain reflectometry circuit, electrically connected to the coupling capacitor and operable, in conjunction with the coupling capacitor, to superimpose and extract time domain reflectometry signals over/from the elevated voltage of the contact piece; and/or
v) wherein the coupling capacitor is operable to superimpose a frequency domain reflectometry signal over the elevated voltage of the contact piece, and is operable to extract a frequency domain reflectometry signal from the elevated voltage of the contact piece (e.g. a signal formed by partial reflection of the superimposed signal), the sensored insulation plug further comprises a frequency domain reflectometry circuit, electrically connected to the coupling capacitor and operable, in conjunction with the coupling capacitor, to superimpose and extract frequency domain reflectometry signals over/from the elevated voltage of the contact piece; and/or
vi) wherein the coupling capacitor is operable to detect a partial discharge signal in the elevated voltage of the contact piece, the sensored insulation plug further comprises a partial discharge detection circuit, electrically connected to the coupling capacitor and operable, in conjunction with the coupling capacitor, to detect a partial discharge signal; and/or
vii) wherein the coupling capacitor is operable to detect presence or absence of an elevated voltage on the contact piece, the sensored insulation plug further comprises a voltage indicator circuit, electrically connected to the coupling capacitor and operable, in conjunction with the coupling capacitor, to detect the presence or the absence of an elevated voltage; and/or
viii) wherein the coupling capacitor is operable to superimpose a node synchronization signal over the elevated voltage of the contact piece, the sensored insulation plug further comprises a synchronization circuit, electrically connected to the coupling capacitor and operable, in conjunction with the coupling capacitor, to generate node synchronization signals and superimpose the node synchronization signals over the elevated voltage of the contact piece; and/or
ix) wherein the coupling capacitor is operable to extract a node synchronization signal from the elevated voltage of the contact piece, the sensored insulation plug further comprises a synchronization circuit, electrically connected to the coupling capacitor and operable, in conjunction with the coupling capacitor, to extract node synchronization signals from the elevated voltage of the contact piece; and/or
x) wherein the coupling capacitor is operable to sense the elevated voltage at a low accuracy of between 10% and 100% of the true elevated voltage, the sensored insulation plug further comprises a low-accuracy voltage sensing circuit, electrically connected to the coupling capacitor and operable, in conjunction with the coupling capacitor, to sense the elevated voltage at a low accuracy of between 10% and 100% of the true elevated voltage; and/or
xi) wherein the coupling capacitor is operable to detect a zero crossing of the elevated voltage, the sensored insulation plug further comprises a zero crossing sensor circuit, electrically connected to the coupling capacitor and operable, in conjunction with the coupling capacitor, to detect a zero crossing of the elevated voltage.

The coupling electrode of the coupling capacitor is electrically connected with the contact piece. It may be conductively connected with the contact piece. In certain embodiments the contact piece comprises a thread, and the coupling electrode of the coupling capacitor is mechanically conductively engaged with the thread. The coupling electrode is thereby mechanically conductively connected with the contact piece.

In certain of these embodiments the thread is arranged at an axial end portion of the contact piece and coaxially with the plug axis. In these embodiments the coupling capacitor may be arranged coaxially with the plug axis. The coupling electrode may be arranged coaxially with the plug axis. The counter electrode may be arranged coaxially with the plug axis.

The discrete coupling capacitor has a certain extension in axial directions. The tubular sensing electrode may be arranged coaxially around an axial section of the coupling capacitor.

The contact piece is on the same elevated voltage as the coupling electrode to which it is electrically connected. The sensing electrode may be arranged around the entire high-voltage electrode or around a portion of the high-voltage electrode. The sensing electrode may be arranged around the contact piece, or it may be arranged around an axial section of the contact piece. The sensing electrode may be arranged around the coupling electrode or around an axial section of the coupling electrode. Therefore, in certain embodiments the sensing electrode is arranged around an axial section of the contact piece and/or around an axial section of the coupling electrode.

Specifically, the tubular sensing electrode may have a first axial section and a second axial section. The first axial section of the tubular sensing electrode may be arranged around an axial section of the coupling capacitor, and the second axial section of the tubular sensing electrode may be arranged around an axial section of the contact piece. Arrangement of the sensing electrode around a section of the coupling capacitor and an axial section of the contact piece may provide more flexibility on placement of the sensing electrode in axial directions. It may also enable the use of an axially-longer sensing electrode which may help obtain a larger capacitance of the sensing capacitor, resulting in a stronger signal and higher sensing precision.

A traditional power distribution network can be turned particularly easily into a sensored power distribution network by replacing a traditional, non-sensored insulation plug in a separable connector of the network with a sensored insulation plug according to the present disclosure. The present disclosure therefore also provides a power distribution network for distributing electrical power at medium or high voltage and comprising i) a sensored insulation plug as described herein, ii) an electrical apparatus, such as a switchgear or a transformer, iii) a power cable, and iv) a separable connector, connected to an end of the power cable, for connecting the power cable to the electrical apparatus, the separable connector having a rear cavity and a connection element on medium or high voltage when in use, accessible through the rear cavity; wherein the sensored insulation plug is arranged in the rear cavity and wherein the contact piece of the sensored insulation plug is electrically connected to the connection element.

The present disclosure also provides a process of upgrading a traditional separable connector to a sensored separable connector by replacing its traditional (sensored or non-sensored) insulation plug with a sensored insulation plug according to the present disclosure. Since no other elements of the separable connector need to be changed or adapted, and no external power needs to be supplied, this upgrading is particularly quick and requires very little peripheral resources. The present disclosure also provides a process of upgrading a separable connector, comprising
a) providing a sensored insulation plug according to the present disclosure, and providing a medium voltage or high-voltage separable connector, suitable for connecting a power cable to an electrical apparatus in a medium-voltage or high-voltage power distribution network, such as to a switchgear or to a transformer, the separable connector having a rear cavity and a connection element on medium or high voltage when in use, accessible through the rear cavity;
b) inserting the sensored insulation plug into the rear cavity;
c) electrically connecting the contact piece with the connection element.

### BRIEF DESCRIPTION OF THE DRAWINGS

The following Figures illustrate specific aspects of sensored insulation plugs according to the present disclosure.

FIG. 1 Sectional view of a separable connector and a first sensored insulation plug according to the present disclosure;

FIG. 2 Circuit diagram of a voltage divider assembly in which a sensored insulation plug according to the present disclosure can be used;

FIG. 3 Sectional view of the first sensored insulation plug according to the present disclosure;

FIG. 4 Sectional view of a second sensored insulation plug according to the present disclosure; and

FIG. 5 Functional block diagram of a system comprising a sensored insulation plug according to the present disclosure.

### DETAILED DESCRIPTION

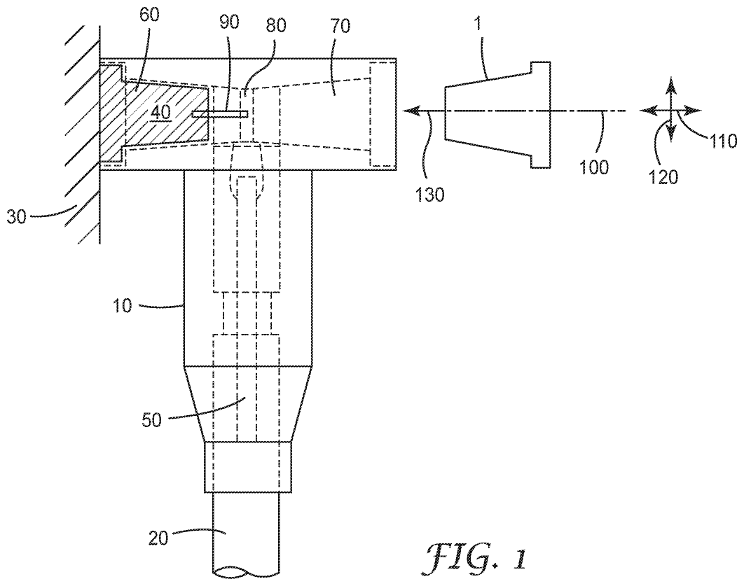

The sectional view of FIG. 1 illustrates a separable connector 10 and a first sensored insulation plug 1 according to the present disclosure. The separable connector 10 is arranged at an end of a medium-voltage power cable 20 and connects, via a bushing 40, the power-carrying central conductor 50 of the cable 20 to a medium-voltage switchgear 30 in a power distribution network of a national grid.

The separable connector 10 is a T-shaped separable connector 10 and comprises a front cavity 60 for receiving the bushing 40, and a rear cavity 70 for receiving an insulation plug of a matching shape. The insulation plug may be a traditional insulation plug without elements of a sensor or a sensored insulation plug 1 according to the present disclosure, shown in FIG. 1 to the right of the rear cavity 70, before being inserted into the rear cavity 70. A traditional insulation plug and a sensored insulation plug 1 according to the present disclosure both serve to electrically insulate a connection element 80 of the separable connector 10, which is electrically connected to the central conductor 50 of the cable 20 and can be electrically and mechanically connected to a conductive component of the bushing 40 via a threaded stud 90. In use, the connection element 80 is on the elevated voltage of the central conductor 50 of the cable.

The body of the first sensored insulation plug 1, just like a traditional insulation plug, has an overall frustoconical outer shape, generally rotationally symmetric about a plug axis 100 which defines axial directions 110 and radial directions 120, which are directions orthogonal to the axial directions 110. The sensored insulation plug 1 can be inserted into the rear cavity 70 by moving it axially in an axial insertion direction 130 into the rear cavity 70 where it is turned by several revolutions about the plug axis 100 to be threadedly engaged—and thereby electrically connected—with the connection element 80 on elevated voltage. The geometry of the sensored insulation plug 1 is adapted to conform to ANSI/IEEE standard 386 to be suitable for a greater number of separable connectors. Depending on where the sensored insulation plug 1 is to be used, it could alternatively be adapted to conform to other standards or be adapted to fit into the most common types of separable connectors in a specific area of the world.

The sensored insulation plug 1 comprises a sensing capacitor and a coupling capacitor, which can both be electrically connected to the connection element 80 on elevated voltage. The sensing capacitor is operable as a high-voltage capacitor in a sensing voltage divider for sensing the elevated voltage, and the coupling capacitor is operable for harvesting energy from the elevated voltage of the high-voltage electrode and for superimposing a communication voltage signal over the elevated voltage of the connection element 80 and of the cable conductor 50.

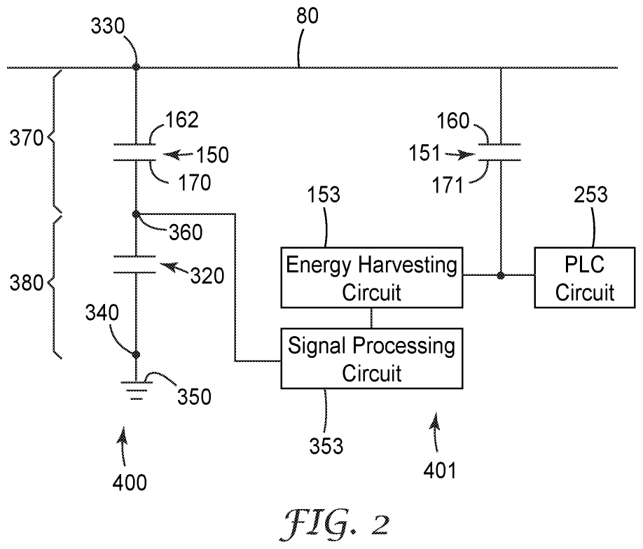

FIG. 2 is a circuit diagram of a sensing voltage divider 400 for sensing the elevated voltage of the separable connector 10 at high precision and of a harvesting and powerline communication setup 401 in which the sensored insulation plug 1 of the present disclosure can be used.

The sensing voltage divider 400 for sensing the elevated voltage of the separable connector 10 at high-precision is shown electrically connected to the elevated voltage of a connection element 80 of the separable connector 10 on medium or high (i.e. on elevated) voltage. The sensing voltage divider 400 comprises a high-voltage capacitor 150, corresponding to the sensing capacitor 150 in the sensored insulation plug 1 described below, and a low-voltage capacitor 320. These two capacitors are electrically connected in series between a high-voltage contact 330 and a grounding contact 340, held on electrical ground 350.

The high-voltage contact 330 facilitates electrical connection to the connection element 80 on elevated voltage. The grounding contact 340 facilitates connection of the sensing voltage divider 400 to electrical ground 350.

A signal contact 360 is arranged electrically between a high-voltage portion 370 and a low-voltage portion 380 of the sensing voltage divider 400. At the signal contact 360, a divided voltage, also referred to herein as the signal voltage, can be picked up, which varies proportionally with the elevated voltage of the connection element 80. The dividing ratio, i.e. the proportionality factor between the elevated voltage and the signal voltage, depends on the ratio of the total impedance of the high-voltage portion 370 to the total impedance of the low-voltage portion 380 of the voltage divider 400. By measuring the signal voltage of the signal contact 360 and applying the proportionality factor, the elevated voltage of the connection element 80 can be sensed.

In the illustrated embodiment, the high-voltage portion 370 comprises only one capacitor, namely the sensing capacitor 150, with its high-voltage electrode 162 and its sensing electrode 170. In other embodiments the high-voltage portion 370 may comprise, beyond the sensing capacitor 150, one or more further capacitors. It may comprise, beyond the sensing capacitor 150, one or more further impedance elements, such as one or more resistors and/or one or more inductors.

Similarly, in the illustrated sensing voltage divider 400, the low-voltage portion 380 comprises only one capacitor, namely the low-voltage capacitor 320. In other embodiments the low-voltage portion 380 may comprise, beyond the low-voltage capacitor 320, one or more further capacitors. It may comprise, beyond the low-voltage capacitor 320, one or more further impedance elements, such as one or more resistors and/or one or more inductors.

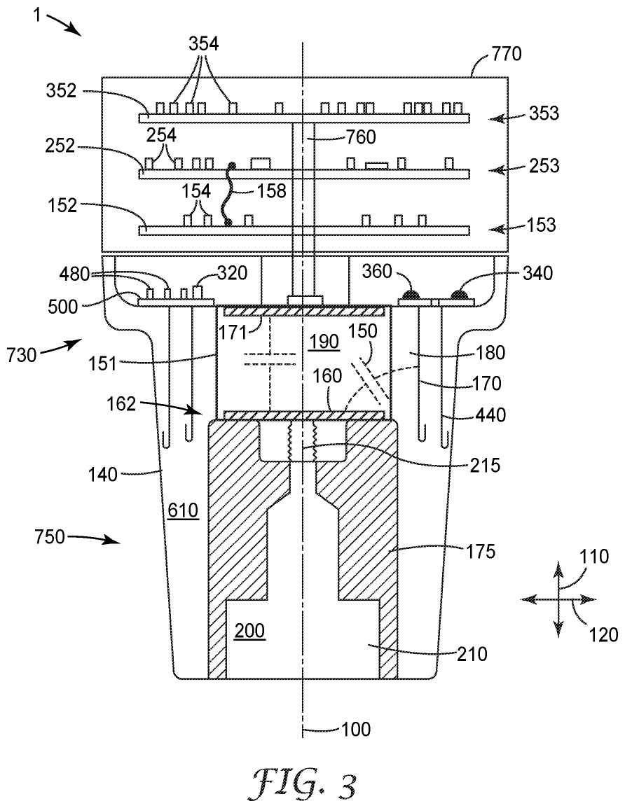

The harvesting and powerline communication setup 401 for harvesting energy from the elevated voltage and for facilitating powerline communication is also electrically connected, via a coupling capacitor 151, to the connection element 80 of the separable connector 10 on medium or high (i.e. elevated) voltage. The harvesting and powerline communication setup 401 comprises the coupling capacitor 151, a harvesting circuit 153, a powerline communication (PLC) circuit 253 and a signal processing circuit 353. The coupling capacitor 151 is a discrete capacitor which exists independently from structural elements of the sensored insulation plug 1. A coupling electrode 160 of the coupling capacitor 151 is electrically conductively connected with the high-voltage electrode 162 of the sensing capacitor 150. Physically the coupling electrode 160 is comprised in the high-voltage electrode 162. as shown in FIG. 3. In the circuit diagram of FIG. 2 they are anyhow drawn separate as they are part of two different capacitors 150, 151. A counter electrode 171 of the coupling capacitor 151 is electrically connected with the harvesting circuit 153 and the PLC circuit 253. The signal processing circuit 353 is connected to the signal contact 360 to pick up the signal voltage from the sensing voltage divider 400. The signal processing circuit 353 processes the signal voltage and digitizes it for transmission in a corresponding communication voltage signal generated by the PLC circuit 253. The signal processing circuit 353 and the PLC circuit 253 are powered by energy harvested in the harvesting circuit 153.

FIG. 3 shows, in a sectional view, the first sensored insulation plug 1 according to the present disclosure in greater detail. The sensored insulation plug 1 comprises a plug body 140 of generally frustoconical shape, formed by a solidified insulating material 610, namely an electrically insulating hardened resin 610. The plug body 140 has, in axial directions 110, a low-voltage end portion 730 and an opposed high-voltage end portion 750, which comprises the contact piece 175 and is, in use, closer to the connection element 80 of the separable connector 10.

The sensored insulation plug 1 further comprises an integrated sensing capacitor 150 formed by a high-voltage electrode 162 and a tubular sensing electrode 170, and a discrete coupling capacitor 151 formed by a coupling electrode 160, which is comprised in the high-voltage electrode 162, and an opposed counter electrode 171. The coupling capacitor 151 is a single-layer ceramic capacitor 151. The dielectric 190 of the discrete coupling capacitor 151 is arranged between the coupling electrode 160 and the counter electrode 171.

In this embodiment the contact piece 175 and the coupling electrode 160 form the high-voltage electrode 162 of the sensing capacitor 150. The dielectric of the sensing capacitor 150 comprises a first portion 180 of the insulating material 610 of the plug body 140, this first portion 180 is located radially between an outer surface the coupling capacitor 151 and the sensing electrode 170. The dielectric of the sensing capacitor 150 also comprises a portion of the dielectric 190 of the coupling capacitor 151.

The tubular sensing electrode 170 is arranged coaxially around an axial section of the high-voltage electrode 162. Specifically, it is arranged coaxially around an axial section of the contact piece 175 and around the coupling electrode 160 of the coupling capacitor 151. The contact piece 175 and the coupling electrode 160 are electrically connected with each other via a surface contact and via the conductive screw 215 and are thus on the same elevated voltage when the sensored insulation plug 1 is in use.

The sensored insulation plug 1 further comprises a tubular shield electrode 440, arranged coaxially around the sensing electrode 170. The shield electrode 440 can be grounded to shield the sensing electrode 170 against external electrical fields and thereby obtain a higher precision in sensing the elevated voltage.

The coupling capacitor 151, its coupling electrode 160 and its counter electrode 171, and the sensing electrode 170 are each rotationally symmetric about a plug axis 100 and arranged coaxially with each other and with the plug axis 100.

The sensored insulation plug 1 comprises a contact piece 175 to mechanically and conductively connect the sensored insulation plug 1 with the connection element 80 of the separable connector 10 on elevated voltage. This contact piece 175 is generally rotationally symmetric about the plug axis 100 and has an engagement portion 210 for connecting the contact piece 175 mechanically and electrically with the connection element 80 of the separable connector 10. For that purpose, the engagement portion 210 comprises a threaded recess 200.

At its opposite end, the contact piece 175 is mechanically and electrically conductively connected with the coupling electrode 160 of the coupling capacitor 151 through a surface contact and a conductive screw 215 so that these elements are on the same elevated voltage when in use.

The sensing electrode 170, the shield electrode 440 and the coupling capacitor 151 are each completely surrounded by the insulating material 610 of the plug body 140. In other words, they are each embedded in the insulating material 610. The major surfaces of the sensing electrode 170 and the outer surface of the coupling capacitor 151 are in surface contact with the surrounding insulating material 610 of the plug body 140 in which the sensing electrode 170 and the coupling capacitor 151 are embedded.

The insulating material 610 of the plug body 140 is a hardened epoxy resin with certain fillers. In manufacturing, the resin in its liquid state is cast or molded around the coupling capacitor 151, the sensing electrode 170 and the shield electrode 440 in a mold that determines the outer shape of the plug body 140 of the sensored insulation plug 1. A major part of the resin 610 flows under pressure around the sensing electrode 170, around the shield electrode 440 and around the coupling capacitor 151. The resin 610 is then cured or hardened to solidify, resulting in a solid insulating plug body 140 in which the sensing electrode 170, the shield electrode 440 and the coupling capacitor 151 are embedded. The electrical breakdown strength of the insulating material 610 is high enough to reliably prevent electric discharges between the coupling electrode 160 on elevated voltage and the sensing electrode 170 and between the coupling electrode 160 on elevated voltage and the shield electrode 440.

The sensing electrode 170 is mechanically supported by a flat, rigid circuit board 500 of generally annular shape, arranged coaxially with the plug axis 100. The circuit board 500 comprises conductive traces by which electric and electronic components 480, such as the sensing electrode 170, arranged respectively on the upper surface and on the lower surface of the circuit board 500, are electrically connected with each other. In particular, a low-voltage capacitor 320 is arranged on the circuit board 500. This low-voltage capacitor 320 is electrically connected in series between the sensing electrode 170 and a grounding contact 340 which can be externally connected to electrical ground 350. The low-voltage capacitor 320 forms the low-voltage portion 380 of a sensing voltage divider 400 for sensing the elevated voltage, with the sensing capacitor 150 forming the high-voltage portion 370 of the sensing voltage divider 400, as shown in FIG. 2. The divided voltage, i.e. the “signal voltage”, of the sensing voltage divider 400 can be accessed at a signal contact 360 on the circuit board 500. As is generally known for voltage dividers, the signal voltage varies proportionally with the elevated voltage of the high-voltage electrode 162, so that the elevated voltage of the high-voltage electrode 162—and thereby the elevated voltage of the connection element 80 of the separable connector 10—can be determined by measuring the signal voltage at the signal contact 360 and multiplying it with the dividing ratio of the sensing voltage divider 400.

The coupling capacitor 151 is a discrete capacitor that exists independently from any structural features of the sensored insulation plug 1. It can be obtained as a standalone element and can then be arranged in the sensored insulation plug 1.

The coupling capacitor 151 is operable to harvest energy from the elevated voltage. For that purpose, the counter electrode 171 is electrically connected with a harvesting circuit 153 via a conductive pin 760. The harvesting circuit 153 comprises electric and electronic components 154 and a harvesting circuit board 152 on which the components 154 are arranged, for harvesting electrical energy and storing the harvested energy for powering other electronic components. One of the electric components 154 is a rectifier (not shown) which is required for converting AC currents into DC currents that can be used to power other components or the charge of which can be stored in a storage capacitor (not shown). The harvesting circuit 153 is arranged in an end cap 770, which serves to cover the exposed low-voltage end portion 730 of the plug body 140.

The coupling capacitor 151 of the embodiment shown in FIG. 3 is also operable to superimpose a communication voltage signal over the elevated voltage of the contact piece 175 and to extract a communication voltage signal from the elevated voltage of the contact piece 175. For the purposes of superimposing and extracting communication voltage signals, the counter electrode 171 is electrically connected with a powerline communication circuit 253, also referred to herein as a PLC circuit 253, via the conductive pin 760. The PLC circuit 253 comprises electronic components 254 and a PLC circuit board 252 on which the components 254 are arranged, for superimposing and extracting communication signals. The PLC circuit 253 is also arranged in the end cap 770.

The signal voltage at the signal contact 360 varies proportionally with the elevated voltage. It facilitates sensing of the elevated voltage at high precision and is the output of the sensing voltage divider 400. In order to generate and transmit a communication voltage signal comprising data representing this signal voltage, the signal voltage is processed and digitized using an analogue-to-digital converter (“A/D converter” or “ADC”) and other electronic components. The first sensored insulation plug 1 therefore comprises a signal processing circuit 353 which is electrically connected (not shown) to the signal contact 360 to pick up the signal voltage. The signal processing circuit 353 comprises electronic components 354 and a signal processing circuit board 352 on which the components 354 are arranged, for processing and digitizing the signal voltage. The processed and digitized signal voltage is conducted to the PLC circuit 253, e.g. via a wire (not shown), which processes it further and transmits a value of the signal voltage by superimposing a corresponding communication voltage signal over the elevated voltage. The signal processing circuit 353 is powered by energy harvested via the coupling capacitor 151 and the harvesting circuit 153 and is therefore connected to the harvesting circuit 153, e.g. via a wire (not shown). The signal processing circuit 353 is also arranged in the end cap 770.

The PLC circuit 253 is connected with the signal contact 360 by a signal wire (not shown). The PLC circuit 253 is operationally connected via an interface wire 158 with the harvesting circuit 153 in a suitable manner such that electrical energy harvested by the harvesting circuit 153 is useable to supply energy to the PLC circuit 253.

The PLC circuit 253 facilitates powerline communication with other elements of a communication network, e.g. a network of the network operator. In particular it facilitates PLC communication with other sensored insulation plugs 1, 2 of the type described herein. Generally, the outgoing PLC communication signal preferably contains data representing a value of the sensed voltage in analogue or digital form. Incoming communication may contain signals like, for example, control signals or sync signals from other nodes in the operator's network or from a central network control center.

In the embodiment of FIG. 3 the harvesting circuit 153, the PLC circuit 253 and the signal processing circuit 353 are arranged in an end cap 770 attached to the plug body 140. It is contemplated that in alternative embodiments one of these circuits 153, 253, 353, or two of these circuits 153, 253, 353, or all of these circuits 153, 253, 353 may be arranged remote from the plug body 140.

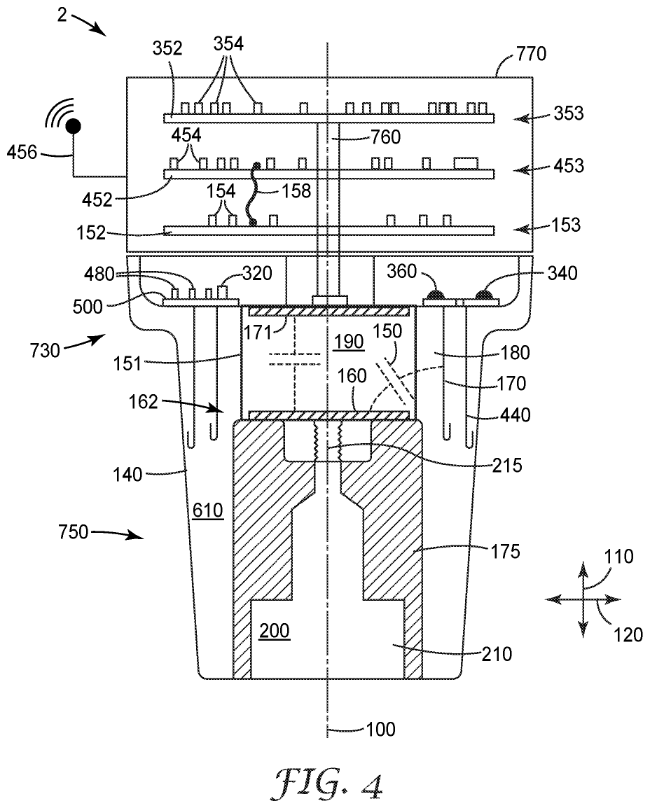

FIG. 4 is a sectional view of a second sensored insulation plug 2 according to the present disclosure. The second sensored insulation plug 2 is identical with the first sensored insulation plug 1 shown in FIG. 3, except that it transmits and receives a communication voltage signal wirelessly via an antenna instead of via powerline communication.

Instead of the PLC circuit 253, the second sensored insulation plug 2 comprises a wireless circuit 453, arranged in the end cap 770. The wireless circuit 453 comprises electronic components 454 and a wireless circuit board 452 on which the components 454 are arranged. The wireless circuit 453 is operable to wirelessly receive and transmit communication voltage signals, e. g. communication voltage signals comprising data representing the signal voltage or synchronization signals. The wireless circuit 453 is operationally connected with an antenna 456 mounted on an external surface of the end cap 770. The antenna 456 facilitates wireless receiving and transmission of such communication voltage signals.

The wireless circuit 453 facilitates wireless communication with other elements of a communication network, e.g. a network of the network operator or a public mobile communication network. In particular, it facilitates wireless communication with other sensored insulation plugs 1, 2 of the type described herein. Generally, the outgoing communication preferably contains data representing a value of the sensed voltage in analogue or digital form. Incoming communication may contain control signals or sync signals from other nodes in the network or from a central network control center.

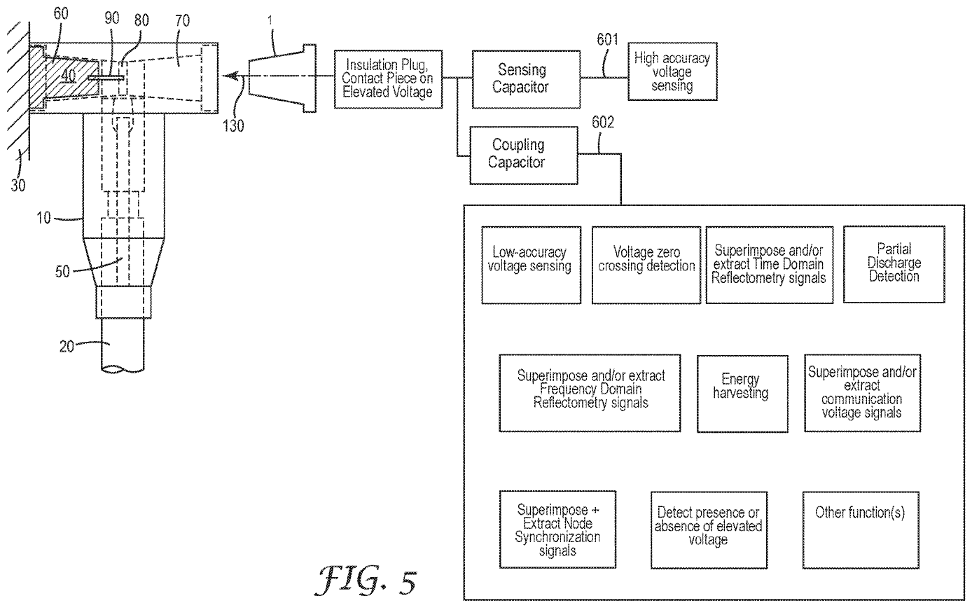

FIG. 5 is a functional block diagram of a sensing system comprising a sensored insulation plug 1 according to the present disclosure. There are several diagnostic tools that can be used for accurate pre-fault and fault identification in a power cable 20, such as partial discharge detection, reflectometry and voltage monitoring and source location analyses as well as functions that can be enabled to support basic functioning of an electronic device in the field like power harvesting. The sensored insulation plug 1 according to the present disclosure provides a coupling solution that is simple, low cost, and has a compact footprint, that is easy to install and maintain and also provides high performance results, rather than a separate sensor or a separate coupling component for each specific function.

In FIG. 5, on the left, identical to FIG. 1, a power cable 20 is illustrated which is connected to an electrical apparatus 30 via a separable connector 10. The connection element 80 of the separable connector 10 is electrically insulated by the first insulation plug 1 which is inserted into the cavity 70. The contact piece 175 (FIG. 3) of the sensored insulation plug 1 is electrically connected to the connection element 80, which in turn is on the elevated voltage of the central conductor 50 of the cable 20.

The right side of FIG. 5 illustrates various possible coupling functions of the sensored insulation plug 1. The sensored insulation plug 1 and its coupling capacitor 151 are operable to perform one, several, or all of them. A first capacitive path 601 comprises the integrated sensing capacitor 150. This first capacitive path 601 and the sensing capacitor 150 facilitate high accuracy sensing of the elevated voltage of the contact piece 175. The sensing capacitor 150 is operable as a high-voltage capacitor in a sensing voltage divider 400 for sensing the elevated voltage. The low-voltage portion 380 of this sensing voltage divider 400 may be comprised in the sensored insulation plug 1 or may be a separate set of elements, independent from the sensored insulation plug 1 and/or in a different location from the sensored insulation plug 1.

A second capacitive path 602 in the sensored insulation plug 1 of FIG. 5 comprises the discrete coupling capacitor 151 which is electrically coupled to the elevated voltage of the contact piece 175 and thereby to the central power conductor 50 of the cable 20. The coupling capacitor 151 is operable—in conjunction with respective dedicated electronic circuits (not shown)—to perform one, or several, or all, of the coupling functions explained above and shown in the large box at the bottom of FIG. 5. These coupling functions are illustrated as different blocks in FIG. 5:
sense the elevated voltage at a low accuracy of between 10% and 100% of the true elevated voltage,
detect a zero crossing of the elevated voltage,
superimpose a time domain reflectometry signal over the elevated voltage of the contact piece, and/or extract a time domain reflectometry signal from the elevated voltage of the contact piece,
detect a partial discharge signal in the elevated voltage of the contact piece,
superimpose a frequency domain reflectometry signal over the elevated voltage of the contact piece, and/or extract a frequency domain reflectometry signal from the elevated voltage of the contact piece,
harvest energy from the elevated voltage of the contact piece,
superimpose a communication voltage signal, such as power line communication voltage signal, over elevated voltage, and/or extract a communication voltage signal, such as a power line communication voltage signal, from the elevated voltage,
superimpose a node synchronization signal over the elevated voltage of the contact piece, and/or extract a node synchronization signal from the elevated voltage of the contact piece, and
detect the presence or absence of an elevated voltage on the contact piece.

Further to these coupling functions, the coupling capacitor 151 may be operable to perform further functions that benefit from the coupling capacitor 151 being electrically connected to the power conductor 50 and being integrated into a sensored insulation plug 1 with its space-saving form factor.

1. Sensored insulation plug for being inserted into a rear cavity of a medium voltage or high-voltage separable connector in a power distribution network of a national grid, and operable to insulate a connection element of the separable connector on an elevated voltage and to sense the elevated voltage,
the sensored insulation plug comprising
a) a plug body formed by a solidified insulating material and rotationally symmetric about a plug axis defining axial directions and radial directions orthogonal to the axial directions,
b) an electrically conductive contact piece, mechanically and conductively connectable with the connection element on elevated voltage;
c) a discrete coupling capacitor operable to
i) harvest energy from the elevated voltage of the contact piece, and/or
ii) superimpose a communication voltage signal, such as a power line communication voltage signal, over the elevated voltage of the contact piece, and/or
iii) extract a communication voltage signal, such as a power line communication voltage signal, from the elevated voltage of the contact piece, and/or
iv) superimpose a time domain reflectometry signal over the elevated voltage of the contact piece, and extract a time domain reflectometry signal from the elevated voltage of the contact piece, and/or
v) superimpose a frequency domain reflectometry signal over the elevated voltage of the contact piece, and extract a frequency domain reflectometry signal from the elevated voltage of the contact piece, and/or
vi) detect a partial discharge signal in the elevated voltage of the contact piece, and/or
vii) detect the presence or absence of an elevated voltage on the contact piece, and/or
viii) superimpose a node synchronization signal over the elevated voltage of the contact piece, and/or
ix) extract a node synchronization signal from the elevated voltage of the contact piece, and/or
x) sense the elevated voltage at a low accuracy of between 5% and 100% of the true elevated voltage, and/or
xi) detect a zero crossing of the elevated voltage,
wherein the coupling capacitor is embedded in the insulating material and comprises a coupling electrode electrically connected to the contact piece and an opposed counter electrode,
d) an integrated sensing capacitor operable as a high-voltage capacitor in a sensing voltage divider for sensing the elevated voltage, the sensing capacitor comprising
i) a high-voltage electrode wherein the high-voltage electrode comprises the coupling electrode and the contact piece;
ii) a tubular sensing electrode embedded in the insulating material and arranged around an axial section of the high-voltage electrode,
iii) a dielectric comprising a portion of the insulating material arranged between the sensing electrode and the coupling capacitor.

2. Sensored insulation plug according to claim 1, wherein the coupling capacitor has a capacitance of 100 picofarad or more.

3. Sensored insulation plug according to any one of the preceding claims, wherein the coupling electrode is flat and oriented parallel to a geometric plane extending in radial directions.

4. Sensored insulation plug according to claim 1, wherein the coupling capacitor is a single-layer capacitor, such as a single-layer ceramic capacitor.

5. Sensored insulation plug according to claim 1, wherein the sensing electrode is arranged around an axial section of the contact piece and/or around an axial section of the coupling electrode.

6. Sensored insulation plug according to claim 1, wherein the discrete coupling capacitor of the sensored insulation plug is operable to harvest energy from the elevated voltage of the contact piece, further comprising a harvesting circuit electrically connected to the counter electrode and operable, in conjunction with the coupling capacitor, to harvest electrical energy from the elevated voltage.

7. Sensored insulation plug according to claim 6, wherein the harvesting circuit comprises a rectifier, connected to the counter electrode, for rectifying a voltage of the counter electrode and optionally wherein the harvesting circuit further comprises a storage capacitor for storing harvested electrical energy.

8. Sensored insulation plug according to claim 6, further comprising an end cap attached to a low-voltage end portion of the plug body, wherein the harvesting circuit is arranged in the end cap.

9. Sensored insulation plug according to claim 6, further comprising a signal processing circuit, electrically connected to the sensing electrode, and operable to process a signal voltage of the sensing electrode,
wherein the signal processing circuit is electrically connected to the harvesting circuit such that the signal processing circuit receives electrical energy from the harvesting circuit.

10. Sensored insulation plug according to claim 9, wherein the signal processing circuit comprises an analogue-to-digital converter for digitizing the signal voltage.

11. Sensored insulation plug according to claim 6, further comprising a powerline communication circuit, electrically connected to the coupling capacitor and operable to superimpose, via the coupling capacitor, a communication voltage signal over the elevated voltage, and/or operable to extract, via the coupling capacitor, a communication voltage signal from the elevated voltage,
wherein the powerline communication circuit is electrically connected to the harvesting circuit such that the powerline communication circuit receives electrical energy from the harvesting circuit.

12. Sensored insulation plug according to claim 6, further comprising a wireless communication circuit operable to generate and wirelessly transmit a communication voltage signal to outside the sensored insulation plug, wherein the wireless communication circuit is electrically connected to the harvesting circuit such that the wireless communication circuit receives electrical energy from the harvesting circuit.

13. Sensored insulation plug according to claim 1,
i) wherein the coupling capacitor is operable to harvest energy from the elevated voltage of the contact piece, and wherein the sensored insulation plug further comprises a harvesting circuit, electrically connected to the coupling capacitor and operable, in conjunction with the coupling capacitor, to harvest energy from the elevated voltage of the contact piece; and/or
ii) wherein the coupling capacitor is operable to superimpose a communication voltage signal, such as a power line communication voltage signal, over the elevated voltage of the contact piece, and wherein the sensored insulation plug further comprises a communication superposition circuit, electrically connected to the coupling capacitor and operable to generate communication signals and, in conjunction with the coupling capacitor, to superimpose the communication signals over the elevated voltage of the contact piece; and/or
iii) wherein the coupling capacitor is operable to extract a communication voltage signal, such as a power line communication voltage signal, from the elevated voltage of the contact piece, and wherein the sensored insulation plug further comprises a communication extraction circuit, electrically connected to the coupling capacitor and operable, in conjunction with the coupling capacitor, to extract communication signals from the elevated voltage of the contact piece; and/or
iv) wherein the coupling capacitor is operable to superimpose a time domain reflectometry signal over the elevated voltage of the contact piece, and is operable to extract a time domain reflectometry signal from the elevated voltage of the contact piece, such as a signal formed by partial reflection of the superimposed signal, and wherein the sensored insulation plug further comprises a time domain reflectometry circuit, electrically connected to the coupling capacitor and operable, in conjunction with the coupling capacitor, to superimpose and extract time domain reflectometry signals over/from the elevated voltage of the contact piece; and/or
v) wherein the coupling capacitor is operable to superimpose a frequency domain reflectometry signal over the elevated voltage of the contact piece, and is operable to extract a frequency domain reflectometry signal from the elevated voltage of the contact piece and wherein the sensored insulation plug further comprises a frequency domain reflectometry circuit, electrically connected to the coupling capacitor and operable, in conjunction with the coupling capacitor, to superimpose and extract frequency domain reflectometry signals over/from the elevated voltage of the contact piece; and/or
vi) wherein the coupling capacitor is operable to detect a partial discharge signal in the elevated voltage of the contact piece, and wherein the sensored insulation plug further comprises a partial discharge detection circuit, electrically connected to the coupling capacitor and operable, in conjunction with the coupling capacitor, to detect a partial discharge signal; and/or
vii) wherein the coupling capacitor is operable to detect presence or absence of an elevated voltage on the contact piece, and wherein the sensored insulation plug further comprises a voltage indicator circuit, electrically connected to the coupling capacitor and operable, in conjunction with the coupling capacitor, to detect the presence or the absence of an elevated voltage; and/or
viii) wherein the coupling capacitor is operable to superimpose a node synchronization signal over the elevated voltage of the contact piece, and wherein the sensored insulation plug further comprises a synchronization circuit, electrically connected to the coupling capacitor and operable, in conjunction with the coupling capacitor, to generate node synchronization signals and superimpose the node synchronization signals over the elevated voltage of the contact piece; and/or
ix) wherein the coupling capacitor is operable to extract a node synchronization signal from the elevated voltage of the contact piece, and wherein the sensored insulation plug further comprises a synchronization circuit, electrically connected to the coupling capacitor and operable, in conjunction with the coupling capacitor, to extract node synchronization signals from the elevated voltage of the contact piece; and/or
x) wherein the coupling capacitor is operable to sense the elevated voltage at a low accuracy of between 10% and 100% of the true elevated voltage, and wherein the sensored insulation plug further comprises a low-accuracy voltage sensing circuit, electrically connected to the coupling capacitor and operable, in conjunction with the coupling capacitor, to sense the elevated voltage at a low accuracy of between 10% and 100% of the true elevated voltage; and/or
xi) wherein the coupling capacitor is operable to detect a zero crossing of the elevated voltage, and wherein the sensored insulation plug further comprises a zero crossing sensor circuit, electrically connected to the coupling capacitor and operable, in conjunction with the coupling capacitor, to detect a zero crossing of the elevated voltage.

14. Power distribution network for distributing electrical power at medium or high voltage and comprising
i) a sensored insulation plug according to claim 1,
ii) an electrical apparatus such as a switchgear or a transformer,
iii) a power cable, and
iv) a separable connector, connected to an end of the power cable, for connecting the power cable to the electrical apparatus,
the separable connector having a rear cavity and a connection element on medium or high voltage when in use, accessible through the rear cavity;
wherein the sensored insulation plug is arranged in the rear cavity and wherein the contact piece of the sensored insulation plug is electrically connected to the connection element.

15. Process of upgrading a separable connector, comprising
a) providing a sensored insulation plug according to claim 1, and providing a medium voltage or high-voltage separable connector, suitable for connecting a power cable to an electrical apparatus in a medium-voltage or high-voltage power distribution network, such as to a switchgear or to a transformer, the separable connector having a rear cavity and a connection element on medium or high voltage when in use, accessible through the rear cavity;
b) inserting the sensored insulation plug into the rear cavity;
c) electrically connecting the contact piece with the connection element.
